(19) United States
(12) Patent Application Publication
(10) Pub. No.: US 2024/0286226 A1
(43) Pub. Date: Aug. 29, 2024

(54) LASER PROCESSING DEVICE AND LASER PROCESSING METHOD

(71) Applicant: HAMAMATSU PHOTONICS K.K., Hamamatsu-shi, Shizuoka (JP)

(72) Inventor: Takeshi SAKAMOTO, Hamamatsu-shi, Shizuoka (JP)

(73) Assignee: HAMAMATSU PHOTONICS K.K., Hamamatsu-shi, Shizuoka (JP)

(21) Appl. No.: 18/572,631

(22) PCT Filed: Jun. 28, 2022
(86) PCT No.: PCT/JP2022/025731

§ 371 Date: Dec. 20, 2023

(30) Foreign Application Priority Data
Jun. 30, 2021 (JP) 2021-109420

(51) Int. Cl. B23K 26/57; B23K 26/06; B23K 26/08; B23K 101/40

(52) U.S. Cl. CPC B23K 26/57; B23K 26/0648; B23K 26/08; B23K 2101/40

(57) ABSTRACT

Provided is a laser processing apparatus including: a support unit that supports an object; a light source that outputs laser light; a spatial light modulator that modulates the laser light output from the light source in correspondence with a modulation pattern and outputs the modulated laser light; a converging lens that converges the laser light output from the spatial light modulator toward the object, and forms a converging spot of the laser light in the object; a movement unit that relatively moves the converging spot with respect to the object; and a control unit that controls at least the light source, the spatial light modulator, and the movement unit. The modulation pattern is controlled so that a beam shape of the converging spot becomes an inclined shape on at least the first surface side in relation to the center of the converging spot.

### TECHNICAL FIELD

The present disclosure relates to a laser processing apparatus and a laser processing method.

### BACKGROUND ART

Patent Literature 1 discloses a laser dicing device. The laser dicing device includes a stage that moves a wafer, a laser head that irradiates the wafer with laser light, and a control unit that controls each unit. The laser head has a laser light source that emits processing laser light for forming a modified region inside the wafer, a dichroic mirror and a converging lens that are sequentially arranged on an optical path of the processing laser light, and an AF device.

### CITATION LIST

### Patent Literature

Patent Literature 1: Japanese Patent No. 5743123

### SUMMARY OF INVENTION

### Technical Problem

By the way, in a case of forming the modified region inside the wafer by irradiating the wafer with the laser light, a part of the laser light may be leaked from a surface opposite to a laser light incident surface in the wafer (so-called leaked light may occur). There is a concern that the leaked light may be the cause for a damage of a device or the like that is formed on the surface opposite to the laser light incident surface in the wafer.

Here, an object of the present disclosure is to provide a laser processing apparatus and a laser processing method capable of reducing an influence of a damage caused by leaked light.

### Solution to Problem

A laser processing apparatus according to the present disclosure includes: a support unit configured to support an object; a light source configured to output laser light; a spatial light modulator configured to modulate the laser light output from the light source in correspondence with a modulation pattern and output the modulated laser light; a converging lens configured to converge the laser light output from the spatial light modulator toward the object, and form a converging spot of the laser light in the object; a movement unit configured to relatively move the converging spot with respect to the object; and a control unit configured to control at least the light source, the spatial light modulator, and the movement unit. The object includes a first surface that becomes an incident surface of the laser light, a second surface opposite to the first surface, and first and second regions arranged on the second surface, and a line, along which the converging spot is relatively moved so as to pass between the first region and the second region, is set. Partial portions of the first region and the second region at least on the line side have structures different from each other. The control unit executes first irradiation processing of irradiating the object with the laser light while relatively moving the converging spot along the line in a state in which the converging spot is positioned at a first Z-position on the second surface side in relation to the first surface with respect to a Z-direction intersecting the first surface and the second surface by controlling the light source, the spatial light modulator, and the movement unit. In the first irradiation processing, the control unit controls the modulation pattern to be displayed on the spatial light modulator so that a beam shape of the converging spot in a YZ-plane including a Y-direction intersecting the line and the Z-direction, and the Z-direction becomes an inclined shape that is inclined with respect to the Z-direction on at least the first surface side in relation to the center of the converging spot.

A laser processing method according to the present disclosure is a laser processing method of irradiating an object, which includes a first surface, a second surface opposite to the first surface, and first and second regions arranged along the second surface and in which a line is set to pass between the first region and the second region, with laser light. The laser processing method includes a first irradiation process of irradiating the object with the laser light while relatively moving the converging spot along the line in a state in which the converging spot of the laser light is positioned at a first Z-position on the second surface side in relation to the first surface with respect to a Z-direction intersecting the first surface and the second surface. Partial portions of the first region and the second region at least on the line side have structures different from each other. In the first irradiation process, the laser light is modulated so that a beam shape of the converging spot in a YZ-plane including a Y-direction intersecting the line and the Z-direction, and the Z-direction becomes an inclined shape that is inclined with respect to the Z-direction on at least the first surface side in relation to the center of the converging spot.

In the apparatus and the method, irradiation of the object with the laser light is performed by relatively moving the converging spot of the laser light along the line set to the object. The object includes the first surface that becomes an incident surface of the laser light, the second surface opposite to the first surface, and the first region and the second region arranged along the second surface. The line along which the converging spot is relatively moved is set to pass between the first region and the second region. In addition, when irradiating with the laser light, the beam shape of the converging spot in the YZ-plane is set to be an inclined shape that is inclined with respect to the Z-direction on at least the first surface side in relation to the center of the converging spot. According to the findings of the present inventors, when the beam shape is set to the inclined shape in this manner, it is possible to unevenly distribute a damage caused by leaked light in correspondence with an inclination direction.

That is, in a case where the inclined shape of the converging spot in the YZ-plane is set to be inclined from the second region toward the first region as going from the first surface toward the second surface, it is possible to unevenly distribute the damage caused by the leaked light on the first region side. On the other hand, in a case where the inclined shape of the converging spot in the YZ-plane is set to be inclined from the first region toward the second region as going from the first surface toward the second surface, it is possible to unevenly distribute the damage caused by the leaked light on the second region side. Here, the first region and the second region of the object have structures different from each other at least at partial portions on the line side. Accordingly, according to the apparatus and the method, it is possible to unevenly distribute the damage caused by the leaked light in a region opposite to a region where the partial portion has a structure relatively vulnerable to the leaked light in the first region and the second region by controlling the inclination direction of the converging spot. According to this, according to the apparatus and the method, it is possible to reduce an influence of a damage caused by the leaked light.

In the laser processing apparatus according to the present disclosure, the control unit may execute second irradiation processing of irradiating the object with the laser light while relatively moving the converging spot along the line in a state in which the converging spot is positioned at a second Z-position that is further spaced apart from the second surface in comparison to the first Z-position in the Z-direction by controlling the light source, the spatial light modulator, and the movement unit, and in the second irradiation processing, the control unit may set the beam shape of the converging spot in the YZ-plane to a non-inclined shape along the Z-direction through control of the spatial light modulator. In this case, in the second Z-position that is farther from the second surface where the first region and the second region are arranged, and an influence of the leaked light on the second surface side is small, since the beam shape of the converging spot of the laser light is set to a non-inclined shape along the Z-direction, it is possible to suitably extend a fracture in the Z-direction from a modified region formed in the vicinity of the second Z-position.

In the laser processing apparatus according to the present disclosure, the first region and the second region may be semiconductor devices, respectively, the second region may be provided with a wiring portion at the partial portion, and in the first irradiation processing, the control unit may control the modulation pattern to be displayed on the spatial light modulator so that the beam shape of the converging spot in the YZ-plane becomes a shape that is inclined from the second region toward the first region as going from the first surface toward the second surface on at least the first surface side in relation to the center of the converging spot. Generally, in semiconductor devices, a wiring portion is likely to be damaged by leaked light. Accordingly, when unevenly distributing the damage caused by the leaked light on the first region side opposite to the second region where the wiring portion is provided by controlling the inclined shape as described above, the influence of the damage caused by the leaked light can be reliably reduced.

In the laser processing apparatus according to the present disclosure, the second region may be an active region, the first region may be a region different from the active region, and in the first irradiation processing, the control unit may control the modulation pattern to be displayed on the spatial light modulator so that the beam shape of the converging spot in the YZ-plane becomes a shape that is inclined from the second region toward the first region as going from the first surface toward the second surface on at least the first surface side in relation to the center of the converging spot. In this case, as described above, when unevenly distributing the damage caused by the leaked light on the first region side opposite to the second region that is an active area by controlling the inclined shape as described above, the influence of the damage caused by the leaked light can be reliably reduced.

In the laser processing apparatus according to the present disclosure, the modulation pattern may include a coma aberration pattern configured to apply coma aberration to the laser light, and in the first irradiation processing, the control unit may set the beam shape to the inclined shape by controlling the coma aberration with the coma aberration pattern. In this manner, the inclined shape of the converging spot can be controlled by controlling the coma aberration applied to the laser light.

### Advantageous Effects of Invention

According to the present disclosure, it is possible to provide a laser processing apparatus and a laser processing method capable of reducing an influence of a damage caused by leaked light.

### BRIEF DESCRIPTION OF DRAWINGS

FIG. 1 is a schematic view illustrating a configuration of a laser processing apparatus according to an embodiment.

FIG. 2 is a schematic view illustrating a configuration of a laser irradiation unit illustrated in FIG. 1.

FIG. 3 is a schematic view illustrating a 4f lens unit and the like illustrated in FIG. 2.

FIG. 4 is a schematic view illustrating a cross-section of a spatial light modulator illustrated in FIG. 2.

FIG. 5 is a view illustrating an example of an object.

FIG. 6 is a view illustrating a process of a laser processing method according to the embodiment.

FIG. 7 is a view illustrating another process of the laser processing method according to the embodiment.

FIG. 8 is a view illustrating a shape of a converging spot and an influence of leaked light.

FIG. 9 is a view illustrating an aspect of offsetting a spherical aberration correction pattern.

FIG. 10 is a view illustrating a variation of a beam shape when changing an offset amount of the spherical aberration correction pattern or a coma aberration level of a coma aberration pattern in a plurality of steps.

FIG. 11 illustrates profiles of converging spots in an XY-plane.

FIG. 12 is a photograph illustrating an example of processing results corresponding to the coma aberration level.

FIG. 13 is a view illustrating an example of a modulation pattern.

FIG. 14 is a view illustrating an intensity distribution in an entrance pupil plane of a converging lens, and a beam shape of a converging spot.

FIG. 15 is a view illustrating observation results of a beam shape of a converging spot and an intensity distribution of the converging spot.

FIG. 16 is a view illustrating an example of a modulation pattern.

FIG. 17 is a view illustrating another example of an asymmetric modulation pattern.

FIG. 18 is a view illustrating an intensity distribution in the entrance pupil plane of the converging lens, and a beam shape of a converging spot.

FIG. 19 is a schematic cross-sectional view illustrating a converging spot according to a modification example.

FIG. 20 is a view illustrating an object according to the modification example.

FIG. 21 is a view illustrating an object according to another modification example.

FIG. 22 is a view illustrating a beam shape of a converging spot.

FIG. 23 is a view illustrating a beam shape of a converging spot.

FIG. 24 is a view for explaining processing results.

FIG. 25 is a view illustrating an object according to still another modification example.

FIG. 26 is a view for explaining a method of forming an oblique fracture.

### DESCRIPTION OF EMBODIMENTS

Hereinafter, an embodiment will be described in detail with reference to the drawings. In the drawings, the same or corresponding portions are denoted by the same reference numerals, and redundant description may be omitted. In addition, each drawing may indicate an orthogonal coordinate system defined by an X-axis, a Y-axis, and a Z-axis.

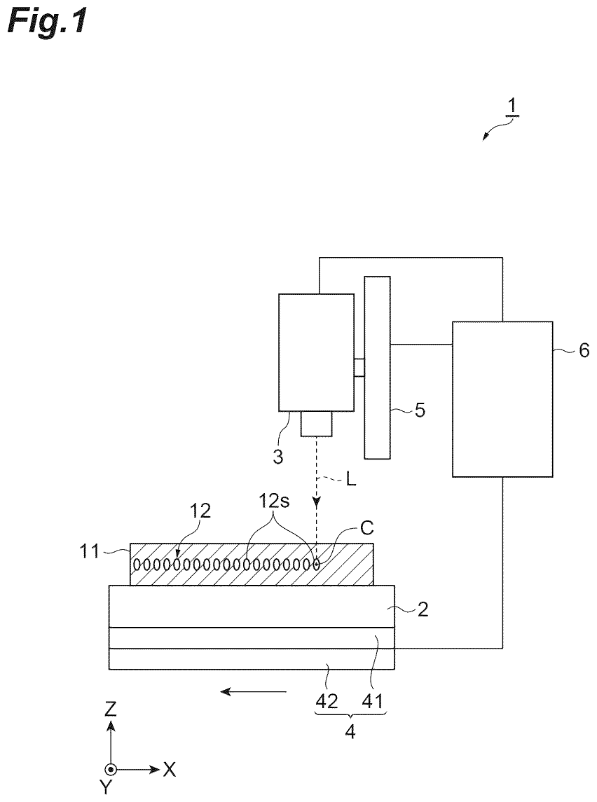

FIG. 1 is a schematic view illustrating a configuration of a laser processing apparatus according to the embodiment. As illustrated in FIG. 1, the laser processing apparatus 1 includes a stage (support unit) 2, a laser irradiation unit 3, drive units (movement units) 4 and 5, and a control unit 6. The laser processing apparatus 1 is a device for forming a modified region 12 in an object 11 by irradiating the object 11 with laser light L.

The stage 2 supports the object 11, for example, by holding a film pasted to the object 11. The stage 2 can rotate around an axial line parallel to the Z-direction as a rotation axis. The stage 2 may be movable along each of the X-direction and the Y-direction. Note that, the X-direction and the Y-direction are a first horizontal direction and a second horizontal direction intersecting (orthogonal to) each other, respectively, and the Z-direction is a vertical direction.

The laser irradiation unit 3 converges the laser light L having permeability with respect to the object 11 and irradiates the object 11 with the laser light L. When the laser light L is converged into the object 11 supported by the stage 2, the laser light L is notably absorbed in a portion corresponding to a converging spot C (for example, a center Ca to be described later) of the laser light L, and the modified region 12 is formed inside the object 11. Note that, although described in detail later, the converging spot C is a region within a predetermined range from a position where the beam intensity of the laser light L is highest or a centroid position of the beam intensity.

The modified region 12 is region that differs from its surrounding unmodified regions in density, refractive index, mechanical strength, and other physical properties. Examples of the modified region 12 include a molten processed region, a crack region, a dielectric breakdown region, a refractive index changing region, and the like. In the modified region 12, a fracture can be formed to be extended from the modified region 12 to the incident side of the laser light L and the opposite side thereof. Such a modified region 12 and a fracture are used, for example, to cut the object 11.

As an example, when the stage 2 is moved along the X-direction and the converging spot C is relatively moved with respect to the object 11 along the X-direction, a plurality of modified spots 12s are formed so as to be arranged in a row along the X-direction. One modified spot 12s is formed by irradiation with one pulse of laser light L. One row of modified region 12 is a set of the plurality of modified spots 12s arranged in a row. Adjacent modified spots 12s may be connected to each other or may be separated from each other depending on a relative moving speed of the converging spot C with respect to the object 11 and the repetition frequency of the laser light L.

The drive unit 4 includes a first movement unit 41 that moves the stage 2 in one direction in a plane intersecting (orthogonal to) the Z-direction, and a second movement unit 42 that moves the stage 2 in another direction in the plane intersecting (orthogonal to) the Z-direction. As an example, the first movement unit 41 moves the stage 2 along the X-direction, and the second movement unit 42 moves the stage 2 along the Y-direction. In addition, the drive unit 4 rotates the stage 2 around an axial line parallel to the Z-direction as the rotation axis. The drive unit 5 supports the laser irradiation unit 3. The drive unit 5 moves the laser irradiation unit 3 along the X-direction, the Y-direction, and the Z-direction. When the stage 2 and/or the laser irradiation unit 3 are moved in a state in which the converging spot C of the laser light L is formed, the converging spot C is relatively moved with respect to the object 11. That is, the drive units 4 and 5 are movement units that move at least one of the stage 2 and the laser irradiation unit 3 so that the converging spot C of the laser light L relatively moves with respect to the object 11.

The control unit 6 controls the operation of the stage 2, the laser irradiation unit 3, and the drive units 4 and 5. The control unit 6 includes a processing unit, a storage unit, and an input receiving unit (not illustrated). The processing unit is configured as a computer device including a processor, a memory, a storage, a communication device, and the like. In the processing unit, the processor executes software (program) read into the memory or the like, and controls reading and writing of data in the memory and the storage, and communication by the communication device. The storage unit is, for example, a hard disk or the like, and stores various data. The input receiving unit is an interface unit that displays various information and receives input of the various information from a user. The input receiving unit constitutes a graphical user interface (GUI).

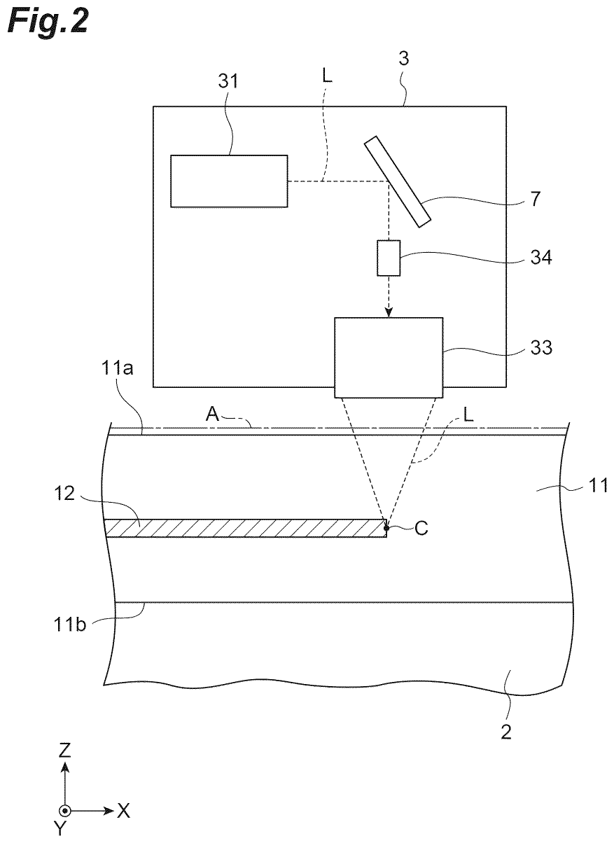

FIG. 2 is a schematic view illustrating a configuration of the laser irradiation unit illustrated in FIG. 1. FIG. 2 illustrates a virtual line A indicating a plan of laser processing. As illustrated in FIG. 2, the laser irradiation unit 3 includes a light source 31, a spatial light modulator 7, a converging lens 33, and a 4f lens unit 34. The light source 31 outputs the laser light L, for example, by a pulse oscillation method. Note that, the laser irradiation unit 3 may not include the light source 31 and may be configured to introduce the laser light L from the outside of the laser irradiation unit 3. The spatial light modulator 7 modulates the laser light L output from the light source 31. The converging lens 33 converges the laser light L modulated by the spatial light modulator 7 and output from the spatial light modulator 7 toward the object 11.

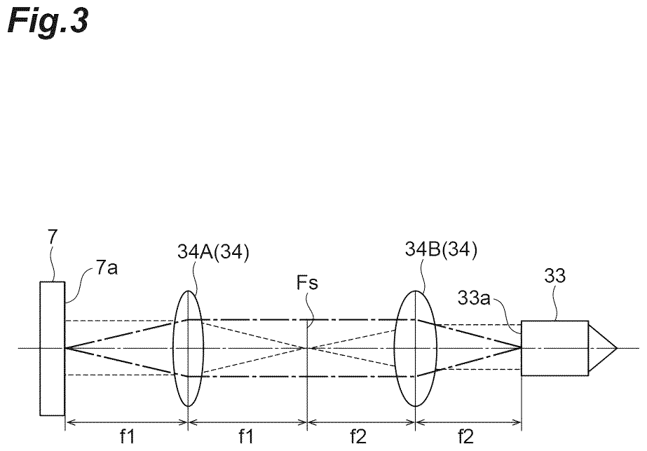

As illustrated in FIG. 3, the 4f lens unit 34 includes a pair of lenses 34A and 34B arranged along an optical path of the laser light L from the spatial light modulator 7 toward the converging lens 33. The pair of lenses 34A and 34B constitutes a both-side telecentric optical system in which a modulation surface 7a of the spatial light modulator 7 and an entrance pupil plane (pupil plane) 33a of the converging lens 33 are in an imaging relationship. According to this, an image of the laser light L on the modulation surface 7a of the spatial light modulator 7 (an image of the laser light L modulated by the spatial light modulator 7) is transferred to (imaged on) the entrance pupil plane 33a of the converging lens 33. Note that, Fs in the drawing indicates a Fourier plane.

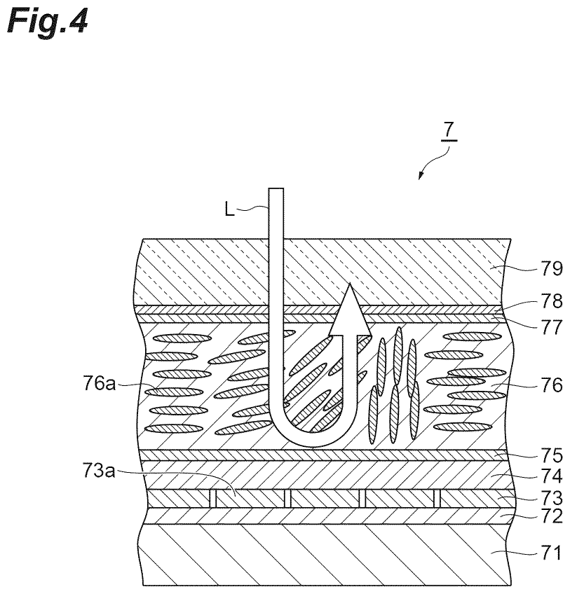

As illustrated in FIG. 4, the spatial light modulator 7 is a spatial light modulator (SLM) of reflective liquid crystal on silicon (LCOS). The spatial light modulator 7 is configured by stacking a drive circuit layer 72, a pixel electrode layer 73, a reflective film 74, an alignment film 75, a liquid crystal layer 76, an alignment film 77, a transparent conductive film 78, and a transparent substrate 79 in this order on a semiconductor substrate 71.

The semiconductor substrate 71 is, for example, a silicon substrate. The drive circuit layer 72 constitutes an active matrix circuit on the semiconductor substrate 71. The pixel electrode layer 73 includes a plurality of pixel electrodes 73a arranged in a matrix along a surface of the semiconductor substrate 71. Each of the pixel electrodes 73a is formed from, for example, a metal material such as aluminum. A voltage is applied to each of the pixel electrodes 73a by the drive circuit layer 72.

The reflective film 74 is, for example, a dielectric multilayer film. The alignment film 75 is provided on a surface of the liquid crystal layer 76 on the reflective film 74 side, and the alignment film 77 is provided on a surface of the liquid crystal layer 76 on a side opposite to the reflective film 74. Each of the alignment films 75 and 77 is formed from, for example, a polymer material such as polyimide, and a contact surface of each of the alignment films 75 and 77 with the liquid crystal layer 76 is subjected to, for example, a rubbing treatment. The alignment films 75 and 77 cause liquid crystal molecules 76a included in the liquid crystal layer 76 to be arranged in a certain direction.

The transparent conductive film 78 is provided on a surface of the transparent substrate 79 on the alignment film 77 side, and faces the pixel electrode layer 73 with the liquid crystal layer 76 and the like interposed therebetween. The transparent substrate 79 is, for example, a glass substrate. The transparent conductive film 78 is formed from, for example, a light transmissive and conductive material such as ITO. The transparent substrate 79 and the transparent conductive film 78 allow the laser light L to pass therethrough.

In the spatial light modulator 7 configured as described above, when a signal indicating a modulation pattern is input from the control unit 6 to the drive circuit layer 72, a voltage corresponding to the signal is applied to each of pixel electrodes 73a, and an electric field is formed between each of the pixel electrodes 73a and the transparent conductive film 78. When the electric field is formed, in the liquid crystal layer 76, the arrangement direction of the liquid crystal molecules 76a varies in each region corresponding to each of the pixel electrodes 73a, and the refractive index varies in each region corresponding to each of the pixel electrodes 73a. This state is a state in which a modulation pattern is displayed on the liquid crystal layer 76. The modulation pattern is for modulating the laser light L.

That is, in a state in which the modulation pattern is displayed on the liquid crystal layer 76, when the laser light L is incident to the liquid crystal layer 76 from the outside through the transparent substrate 79 and the transparent conductive film 78, is reflected by the reflective film 74, and is emitted from the liquid crystal layer 76 to the outside through the transparent conductive film 78 and the transparent substrate 79, the laser light L is modulated in correspondence with the modulation pattern displayed on the liquid crystal layer 76. As described above, according to the spatial light modulator 7, modulation of the laser light L (for example, modulation of an intensity, an amplitude, a phase, polarization, and the like of the laser light L) can be made by appropriately setting the modulation pattern to be displayed on the liquid crystal layer 76. Note that, the modulation surface 7a illustrated in FIG. 3 is, for example, the liquid crystal layer 76.

As described above, the laser light L output from the light source 31 is incident to the converging lens 33 through the spatial light modulator 7 and the 4f lens unit 34, and is converged to the inside of the object 11 by the converging lens 33. According to this, the modified region 12 and a fracture extending from the modified region 12 are formed in the object 11 at the converging spot C. Further, the control unit 6 controls the drive units 4 and 5 to relatively move the converging spot C with respect to the object 11. According to this, the modified region 12 and the fracture are formed along the movement direction of the converging spot C.

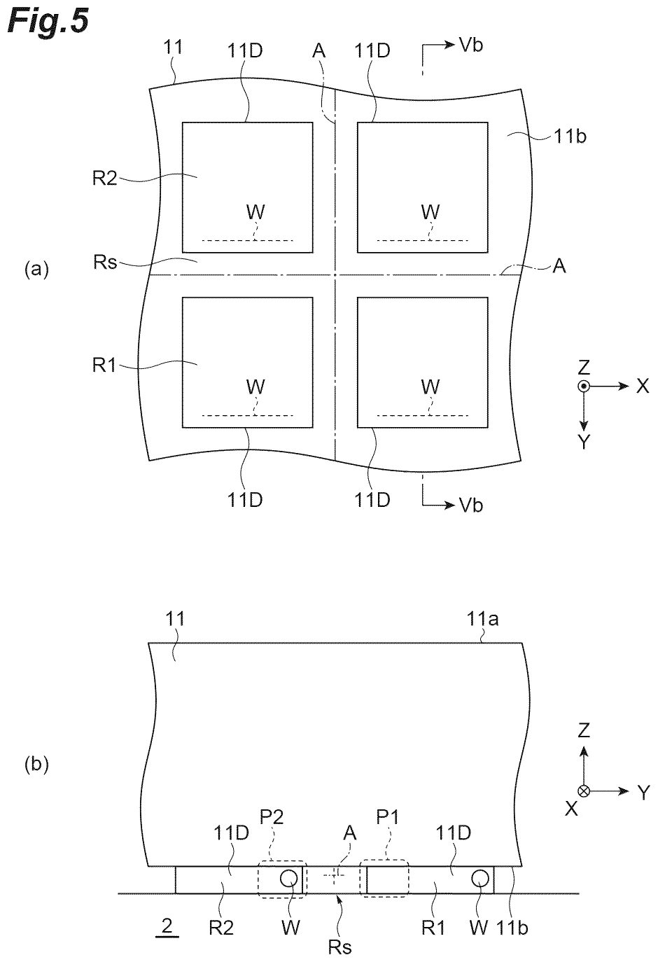

FIG. 5 is a view illustrating an example of an object. FIG. 5(a) is a plan view, and FIG. 5(b) is a cross-section view taken along line Vb-Vb in FIG. 5(a). In FIG. 5(b), hatching is omitted (hereinafter, this is also true of respectively cross-sectional views). As illustrated in FIG. 5, the object 11 includes a first surface 11a, and a second surface 11b opposite to the first surface 11a. The object 11 is supported by the stage 2 so that the first surface 11a and the second surface 11b intersect (orthogonal to) the Z-direction, and the first surface 11a faces to laser irradiation unit 3 side. Accordingly, in the object 11, the first surface 11a becomes an incident surface of the laser light L.

The object 11 includes a plurality of semiconductor devices 11D which are two-dimensionally arranged along the second surface 11b. The semiconductor devices 11D include a wiring portion W formed from, for example, a metal. The wiring portion W is disposed on one side inside one of the semiconductor devices 11D (here, on a positive side in the Y-direction) in a plane view. In addition, each of the semiconductor devices 11D are arranged in the same direction in a plan view.

Accordingly, in one semiconductor device 11D between a pair of semiconductor devices 11D adjacent to each other in the Y-direction, the wiring portion W is not provided at a partial portion P1 facing the other semiconductor device 11D, and in the other semiconductor device 11D, the wiring portion W is provided at a partial portion P2 facing the one semiconductor device 11D.

Here, the one semiconductor device 11D and an area where the semiconductor device 11D is provided in the second surface 11b are referred to as a first region R1, and the other semiconductor device 11D and an area where the semiconductor device 11D is provided in the second surface 11b are referred to as a second region R2. In addition, a street region Rs is interposed between the first region R1 and the second region R2, that is, between the semiconductor devices 11D adjacent to each other. A line A is set to the street region Rs so as to pass between the first region R1 and the second region R2. Accordingly, the partial portions P1 and P2 on the line A side in the first region R1 and the second region R2 have structures different from each other at least in terms of whether or not the wiring portion W is included.

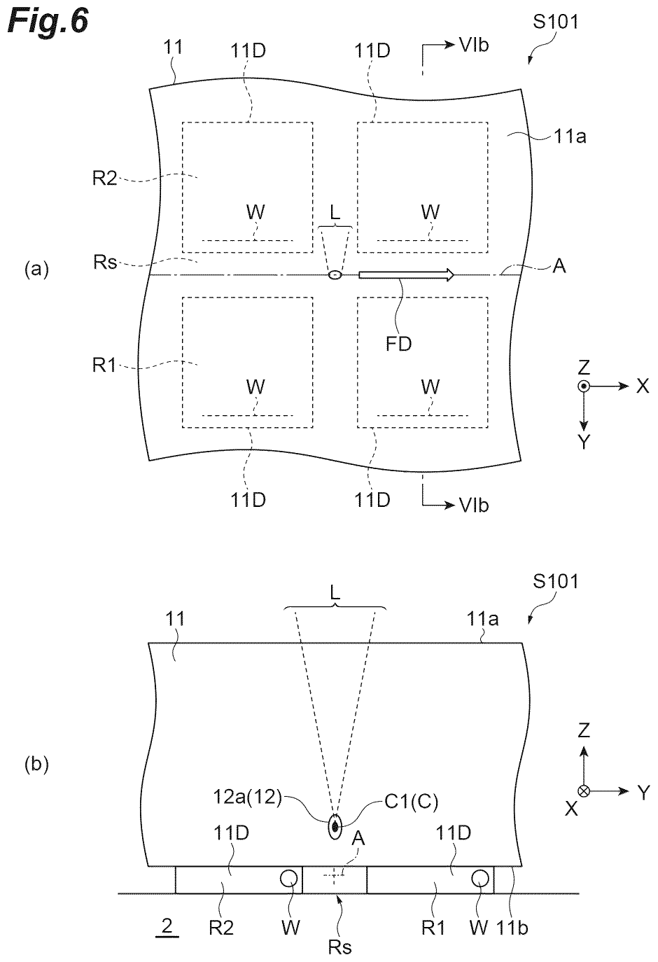

The object 11 is subjected to laser processing as described below. FIG. 6 is a view illustrating a process of a laser processing method according to the embodiment. FIG. 6(a) is a plan view and FIG. 6(b) is a cross-sectional view taken along line VIb-VIb in FIG. 6(a). As illustrated in FIG. 6, first, the laser light L is incident into the object 11 from the first surface 11a side, and a converging spot C1 of the laser light L is formed at a first Z-position in the Z-direction at the inside of the object 11. The first Z-position is a position on the second surface 11b side in relation to the first surface 11a. In this state, the object 11 is irradiated with the laser light L while relatively moving the converging spot C1 of the laser light L along the line A in the X-direction (process S101: first irradiation process).

In the laser processing apparatus 1, in the process S101, the control unit 6 executes first irradiation processing of irradiating the object 11 with the laser light L while relatively moving the converging spot C1 along the line A in a state in which the converging spot C1 is positioned at the first Z-position on the second surface 11b side in relation to the first surface 11a with respect to the Z-direction by controlling the light source 31, the spatial light modulator 7, and the drive units 4 and 5. In this manner, here, the X-direction is set as a processing progress direction FD. According to this, a modified region 12a is formed along the line A at the inside of the object 11 (at the first Z-position). The process S101 and the first irradiation processing can be sequentially performed with respect to a plurality of the lines A.

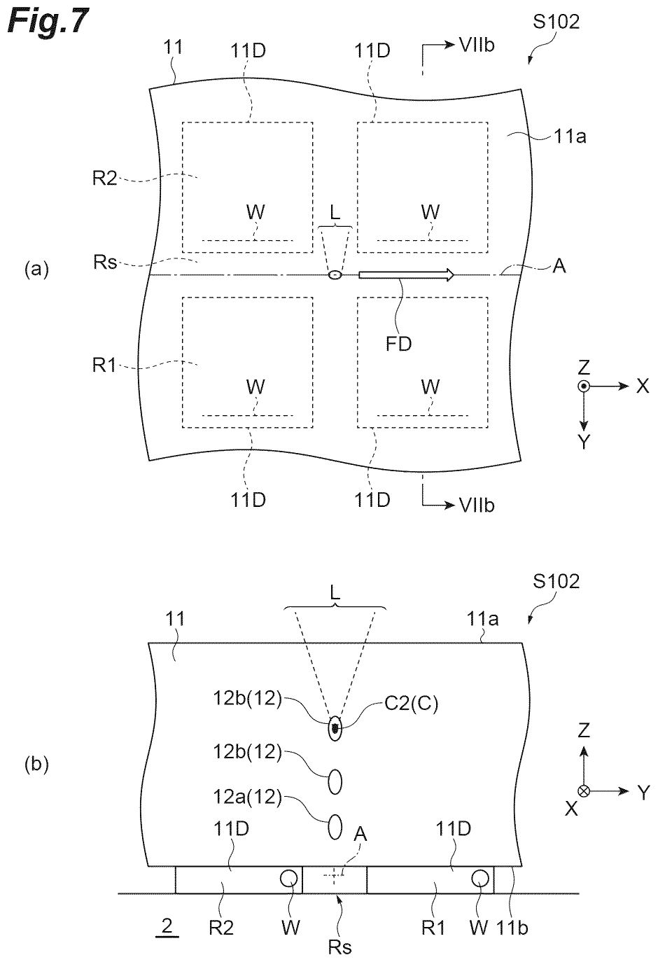

FIG. 7 is a view illustrating another process of the laser processing method according to the embodiment. FIG. 7(a) is a plan view, and FIG. 7(b) is a cross-sectional view taken along line VIIb-VIIb in FIG. 7(a). As illustrated in FIG. 7, subsequently, the laser light L is incident into the object 11 from the first surface 11a side, and a converging spot C2 of the laser light L is formed at a second Z-position in the Z-direction at the inside of the object 11. The second Z-position is a position on a further first surface 11a side in comparison to the first Z-position. In this state, the object 11 is irradiated with the laser light L while relatively moving the converging spot C2 of the laser light L along the line A in the X-direction (process S102).

In the laser processing apparatus 1, in the process S102, the control unit 6 executes second irradiation processing of irradiating the object 11 with the laser light L while relatively moving the converging spot C2 along the line A in a state in which the converging spot C2 is positioned at the second Z-position that is further spaced apart from the second surface 11b in comparison to the first Z-position with respect to the Z-direction by controlling the light source 31, the spatial light modulator 7, and the drive units 4 and 5. According to this, a modified region 12b is formed along the line A at the inside of the object 11 (at the second Z-position). The process S102 and the second irradiation processing can be sequentially performed with respect to a plurality of the lines A.

Note that, in the example illustrated in FIG. 7(b), a state in which two rows of modified regions 12b are formed on the first surface 11a side in comparison to the modified region 12a formed in the vicinity of the first Z-position, is illustrated. Any of the modified regions 12b is formed in the vicinity of the second Z-position on the first surface 11a side in relation to the first Z-position. In this manner, the modified regions 12b can be formed in by any rows when irradiation with the laser light L is performed while the converging spot C2 of the laser light L is positioned at a plurality of (two or more) the second Z-positions. In other words, the first Z-position becomes a position in the Z-direction where the converging spot C1 is positioned when forming the modified region 12a on the most second surface 11b sides during forming a plurality of rows of modified regions 12 arranged in the Z-direction.

Accordingly, in the process S101 and the first irradiation processing, since among a plurality of times of laser processing, processing is performed by positioning the converging spot C1 on the most second surface 11b side, it is highly necessary to consider a damage caused by leaked light from the converging spot C1 to the second surface 11b side, that is, the semiconductor device 11D side. Therefore, in this embodiment, at least in the process S101 and the first irradiation processing, a shape of the converging spot C1 is set to an inclined shape.

Next, the details thereof will be described.

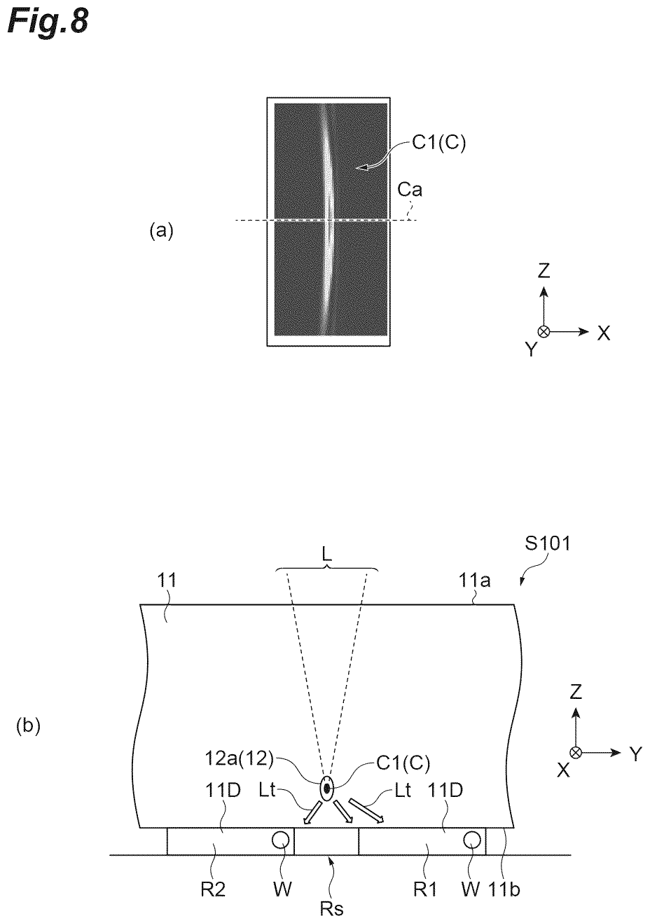

FIG. 8 is a view illustrating a shape of a converging spot and an influence of leaked light. FIG. 8(a) illustrates a beam shape of the converging spot C1 in a YZ-plane. The Y-direction is a direction intersecting (orthogonal to) both the X-direction that is the processing progress direction FD, and the Z-direction. As illustrated in FIG. 8(a), in the process S101 and the first irradiation processing, the laser light L is modulated by using the spatial light modulator 7 so as to set the beam shape of the converging spot C1 in the YZ-plane to an inclined shape that is inclined with respect to the Z-direction on at least the first surface 11a side in relation to the center Ca of the converging spot C1. According to the findings obtained by the present inventors, when the beam shape is set to the inclined shape as described above, it is possible to unevenly distribute a damage caused by the leaked light in correspondence with the inclination direction.

In this embodiment, the beam shape of the converging spot C1 is inclined to a negative side in the Y-direction with respect to the Z-direction on the first surface 11a side in relation to the center Ca, that is, the beam shape is inclined from the second region R2 toward the first region R1 as going from the first surface 11a toward the second surface 11b (as going toward a negative side in the Z-direction). In addition, in this embodiment, the beam shape of the converging spot C1 is inclined to a negative side in the Y-direction with respect to the Z-direction even on the second surface 11b side in relation to the center Ca, that is, the beam shape is inclined from the first region R1 toward the second region R2 as going from the first surface 11a toward the second surface 11b (as going toward the negative side in the Z-direction). According to this, as a whole, the beam shape of the converging spot C1 in the YZ-plane is set to an arcuate shape that is convex toward a positive side in the Y-direction. Note that, the beam shape of the converging spot C1 in the YZ-plane is an intensity distribution of the laser light L at the converging spot C1 in the YZ-plane.

As illustrated in FIG. 8(b), in a case where the inclined shape of the beam shape of the converging spot C1 is controlled as described above, when unevenly distributing the damage caused by leaked light Lt on the first region R1 side opposite to the second region R2 where the wiring portion W is provided, it is possible to reliably reduce an influence of the leaked light Lt on the wiring portion W that is likely to be damaged by the leaked light Lt.

Next, knowledge for forming the beam shape of the converging spot C1 in the YZ-plane to an inclined shape will be described. First, the definition of the converging spot C1 (this is also true of other converging spots) will be specifically described. Here, the converging spot C1 is a region within a predetermined range from the center Ca (for example, a range of ±25 μm from the center Ca with respect to the Z-direction). The center Ca is a position where the beam intensity is highest or a centroid position of the beam intensity. The centroid position of the beam intensity is, for example, a position where the centroid of the beam intensity is positioned on an optical axis of the laser light L in a state in which modulation by a modulation pattern for shifting the optical axis of the laser light L, such as a modulation pattern for branching the laser light L, is not performed.

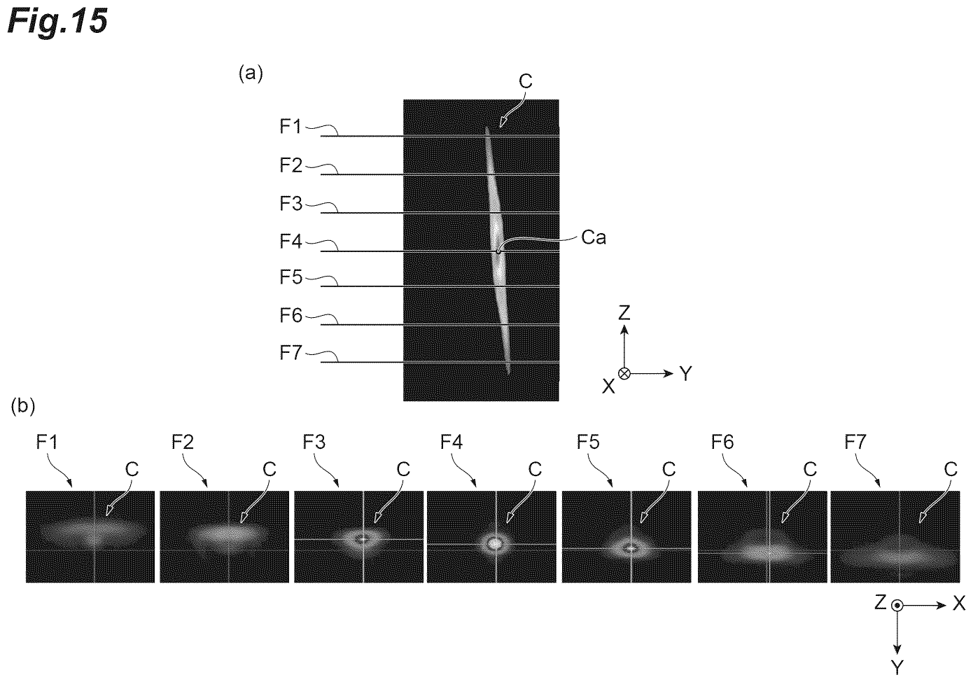

The position where the beam intensity is highest and the centroid position of the beam intensity can be acquired as follows. That is, the object 11 is irradiated with the laser light L in a state in which an output of the laser light L is lowered to a certain an extent in which the modified region 12 is not formed in the object 11 (lower than a processing threshold value). In addition, the reflected light of the laser light L from a surface of the object 11 which is opposite to the incident surface of the laser light L (here, the second surface 11b) is imaged by a camera, for example, with respect to a plurality of positions F1 to F7 in the Z-direction as illustrated in FIG. 15. According to this, the position where the beam intensity is highest and the centroid can be acquired on the basis of the obtained image. Note that, the modified region 12 is formed in the vicinity of the center Ca.

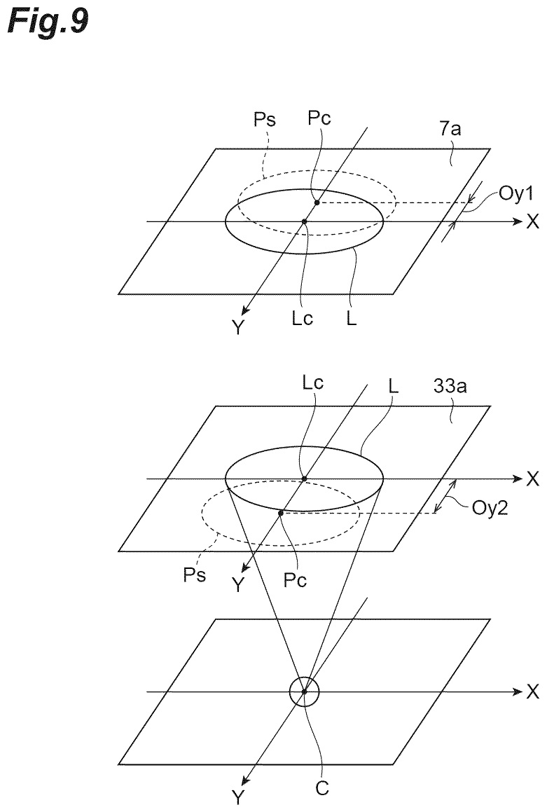

There is a method that offsets the modulation pattern to set the beam shape at the converging spot C1 to an inclined shape. More specifically, various patterns such as a distortion correction pattern for correcting the distortion of a wave front, a grating pattern for branching the laser light, a slit pattern, an astigmatism pattern, a coma aberration pattern, and a spherical aberration correction pattern are displayed on the spatial light modulator 7 (a pattern in which the patterns are superimposed is displayed). As illustrated in FIG. 9, the beam shape of the converging spot C1 can be adjusted by offsetting a spherical aberration correction pattern Ps.

In the example illustrated in FIG. 9, on the modulation surface 7a, a center Pc of the spherical aberration correction pattern Ps is offset to the negative side in the Y-direction by an offset amount Oy1 with respect to the center Lc (of the beam spot) of the laser light L. As described above, the modulation surface 7a is transferred to the entrance pupil plane 33a of the converging lens 33 by the 4f lens unit 34. Therefore, the offset on the modulation surface 7a is an offset to a positive side in the Y-direction on the entrance pupil plane 33a. That is, on the entrance pupil plane 33a, the center Pc of the spherical aberration correction pattern Ps is offset to the positive side in the Y-direction by an offset amount Oy2 from the center Lc of the laser light L and the center of the entrance pupil plane 33a (here, matches the center Lc).

As described above, the beam shape of the converging spot C1 of the laser light L is deformed into an arcuate inclined shape as illustrated in FIG. 8(a) by offsetting the spherical aberration correction pattern Ps. Offsetting of the spherical aberration correction pattern Ps as described above corresponds to imparting of coma aberration to the laser light L. Therefore, the beam shape of the converging spot C1 may be inclined by including the coma aberration pattern for imparting coma aberration to the laser light L in the modulation pattern of the spatial light modulator 7. That is, the modulation pattern includes the coma aberration pattern for imparting coma aberration to the laser light L, and in the process S101 and the first irradiation processing, the control unit 6 may set the beam shape to the inclined shape by controlling the coma aberration with the coma aberration pattern. Note that, as the coma aberration pattern, a pattern which corresponds to the ninth term of the Zernike's polynomial (a Y-component of the third-order coma aberration) and in which coma aberration occurs in the Y-direction can be used.

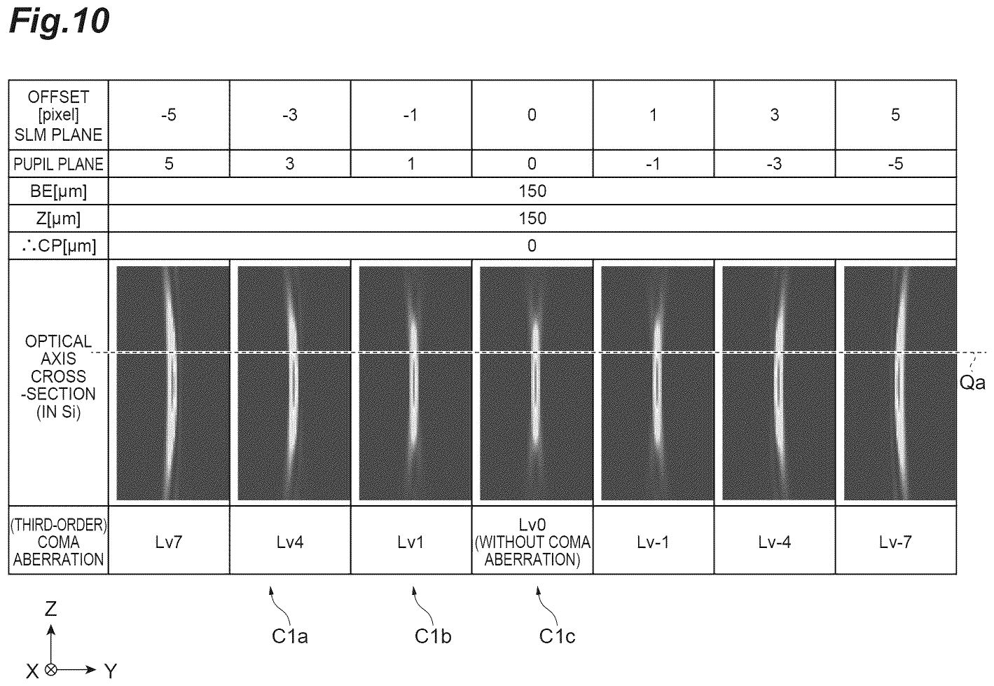

FIG. 10 is a view illustrating a variation of a beam shape when changing an offset amount of the spherical aberration correction pattern or a coma aberration level of the coma aberration pattern in a plurality of steps. In FIG. 10, “offset [pixel] SLM plane” represents an offset amount on the modulation surface 7a. In addition, “(third-order) coma aberration” represents the magnitude of the third-order coma aberration corresponding to the offset amount of the spherical aberration correction pattern Ps. As described above, here, the sign of the offset amount of the spherical aberration correction pattern Ps on the modulation surface 7a, and the sign of the offset amount of the spherical aberration correction pattern Ps on the entrance pupil plane 33a are reversed.

In addition, “BE (μm)” represents a correction amount of the spherical aberration correction pattern Ps, “Z [μm]” represents a converging position of the laser light L in the Z-direction, and “CP [μm]” represents a converging correction amount. As illustrated in FIG. 10, it is possible to cause the beam shape of the converging spot C1 to vary step by step by changing the offset amount (of the center Pc) of the spherical aberration correction pattern Ps step by step, or by changing the coma aberration level of the coma aberration pattern step by step.

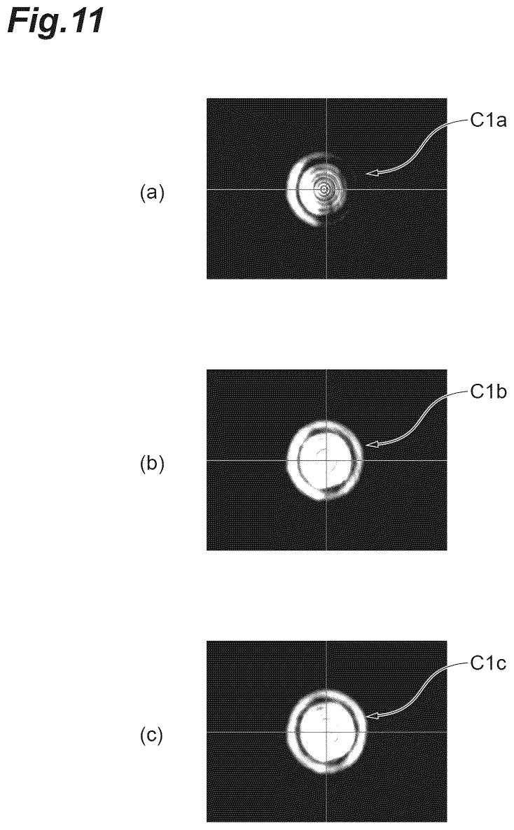

Next, a comparison is made on a converging spot C1a in a case where the coma aberration level is “4”, a converging spot C1b in a case where the coma aberration level is “1”, and a converging spot C1c in a case where the coma aberration level is “0” (in a case where the coma aberration is not imparted) among a plurality of converging spots illustrated in FIG. 10. FIG. 11 illustrates profiles of the respective converging spots in the XY-plane (at a position Qa). As illustrated in FIG. 11, it can be understood that as the coma aberration level increases from the converging spot C1c to the converging spot C1a, a beam intensity distribution in the XY-plane becomes an unevenly distributed state from a uniform state.

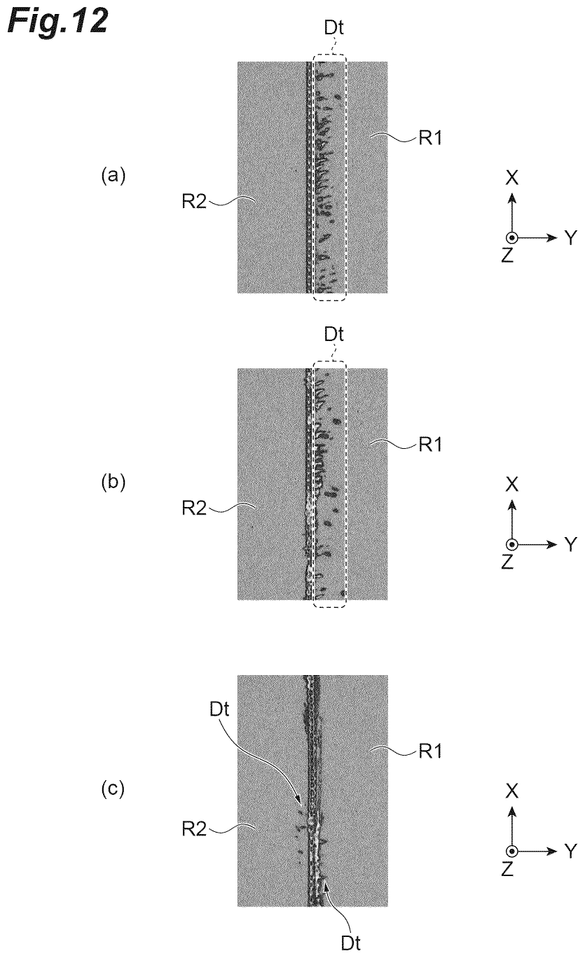

FIG. 12 is a photograph illustrating an example of processing results corresponding to the coma aberration level. FIG. 12(a) illustrates processing results in a case where the coma aberration level is “4” (converging spot C1a), FIG. 12(b) illustrates processing results in a case where the coma aberration level is “1” (converging spot C1b), and FIG. 12(c) illustrates processing results in a case where the coma aberration level is “0” (converging spot C1c). In the examples illustrated in FIGS. 12(a) and 12(b), the damage Dt caused by the leaked light is clearly unevenly distributed in the first region R1, and the damage Dt does not occur in the second region R2.

On the other hand, in the example illustrated in FIG. 12(c), uneven distribution of the damage Dt caused by the leaked light Lt is not shown, and the damage Dt occurs in both the first region R1 and the second region R2. From the results, it can be understood that it is possible to control an influence of the damage Dt caused by the leaked light Lt by setting the beam shape of the converging spot C1 to the inclined shape, as described above. Note that, in the examples illustrated in FIG. 12, the damage Dt is visualized by forming a metal film on the second surface 11b of the object 11 instead of the semiconductor device 11D. In addition, the damage Dt is considered as so-called splash.

As described above, at least in the process S101 and the first irradiation processing, the control unit 6 controls the modulation pattern to be displayed on the spatial light modulator 7 so that the beam shape of the converging spot C1 in the YZ-plane including the Y-direction intersecting the line A and the Z-direction, and the Z-direction becomes an inclined shape that is inclined with respect to the Z-direction on at least the first surface 11a side in relation to the center Ca of the converging spot C1. More specifically, in the process S101 and the first irradiation processing, the control unit 6 controls the modulation pattern to be displayed on the spatial light modulator 7 so that the beam shape of the converging spot C1 in the YZ-plane becomes a shape inclined from the second region R2 toward the first region R1 as going from the first surface 11a toward the second surface 11b on at least the first surface 11a side in relation to the center Ca of the converging spot C1.

On the other hand, with regard to the process S102 and the second irradiation processing, the control unit 6 may control the spatial light modulator 7 so that the beam shape of the converging spot C2 of the laser light L becomes an inclined shape in a similar manner as in the process S101 and the first irradiation processing. However, in the process S102 and the second irradiation processing, since processing is performed by positioning the converging spot C2 at the second Z-position that is relatively spaced apart from the second surface 11b, it is less necessary to consider the damage caused by the leaked light from the converging spot C2 to the second surface 11b side, that is, the semiconductor device 11D side. Accordingly, in this embodiment, in the process S102 and the second irradiation processing, the control unit 6 sets the beam shape of the converging spot C2 in the YZ-plane to a non-inclined shape along the Z-direction by controlling the spatial light modulator 7. As an example, the converging spot C2 having the non-inclined shape can be formed in the same shape as the converging spot C1c by setting the coma aberration level of the modulation pattern to be displayed on the spatial light modulator 7 to “0”.

As described above, in the laser processing apparatus 1 and the laser processing method according to this embodiment, the object 11 is irradiated with the laser light L by relatively moving the converging spot C of the laser light L along the line A set to the object 11. The object 11 includes the first surface 11a that becomes an incident surface of the laser light L, the second surface 11b opposite to the first surface 11a, and the first region R1 and the second region R2 arranged along the second surface 11b. The line A along which the converging spot C is relatively moved is set to pass between the first region R1 and the second region R2. In addition, during irradiation with the laser light L, the beam shape of the converging spot C1 in the YZ-plane is set to an inclined shape with respect to the Z-direction on at least the first surface 11a side in relation to the center Ca of the converging spot C1. When the beam shape is set to the inclined shape in this manner, it is possible to unevenly distribute the damage Dt caused by the leaked light Lt in correspondence with the inclination direction.

That is, in a case where the inclined shape of the converging spot C1 in the YZ-plane is set to be inclined from the second region R2 toward the first region R1 as going from the first surface 11a toward the second surface 11b, it is possible to unevenly distribute the damage Dt caused by the leaked light Lt on the first region R1 side. On the other hand, in a case where the inclined shape of the converging spot C1 in the YZ-plane is set to be inclined from the first region R1 toward the second region R2 as going from the first surface 11a toward the second surface 11b, it is possible to unevenly distribute the damage Dt caused by the leaked light Lt on the second region R2 side.

Here, the first region R1 and the second region R2 of the object 11 have structures different from each other at least at the partial portions P1 and P2 on the line side. Accordingly, according to the laser processing apparatus 1 and the laser processing method according to this embodiment, it is possible to unevenly distribute the damage Dt caused by the leaked light Lt in a region opposite to a region where the partial portions P1 and P2 have a structure relatively vulnerable to the leaked light Lt in the first region R1 and the second region R2 by controlling the inclination direction of the converging spot C1. According to this, according to the laser processing apparatus 1 and the laser processing method according to this embodiment, it is possible to reduce an influence of the damage Dt caused by the leaked light Lt.

In addition, in the laser processing apparatus 1 according to this embodiment, the control unit 6 executes the second irradiation processing of irradiating the object 11 with the laser light L while relatively moving the converging spot C2 along the line A in a state in which the converging spot C2 is positioned at the second Z-position that is further spaced apart from the second surface 11b in comparison to the first Z-position with respect to the Z-direction by controlling the light source 31, the spatial light modulator 7, and the drive units 4 and 5. In the second irradiation processing, the control unit 6 sets the beam shape of the converging spot C2 in the YZ-plane to a non-inclined shape along the Z-direction through control of the spatial light modulator 7. As described above, at the second Z-position that is farther from the second surface 11b where the first region R1 and the second region R2 are arranged, and an influence of the leaked light Lt on the second surface 11b side is small, since the beam shape of the converging spot C2 of the laser light L is set to the non-inclined shape along the Z-direction, it is possible to suitably extend a fracture (vertical fracture) in the Z-direction from the modified region 12b formed in the vicinity of the second Z-position.

In addition, in the laser processing apparatus 1 according to this embodiment, the first region R1 and the second region R2 are semiconductor devices 11D, respectively, and the second region R2 is provided with the wiring portion W at the partial portion P2. In addition, in the first irradiation processing, the control unit 6 controls the modulation pattern to be displayed on the spatial light modulator 7 so that the beam shape of the converging spot C1 in the YZ-plane becomes a shape that is inclined from the second region R2 toward the first region R1 as going from the first surface 11a toward the second surface 11b on at least the first surface 11a side in relation to the center Ca of the converging spot C1. Generally, in semiconductor devices 11D, the wiring portion W is likely to be damaged by leaked light Lt.

Accordingly, when unevenly distributing the damage Dt caused by the leaked light Lt on the first region R1 side opposite to the second region R2 where the wiring portion W is provided by controlling the inclined shape as described above, the influence of the damage Dt caused by the leaked light Lt can be reliably reduced.

In addition, in the laser processing apparatus 1 according to this embodiment, the modulation pattern may include the coma aberration pattern for imparting coma aberration to the laser light L, and in the first irradiation processing, the control unit 6 may set the beam shape to the inclined shape by controlling the coma aberration with the coma aberration pattern. In this manner, the inclined shape of the converging spot C1 can be controlled by controlling the coma aberration that is imparted to the laser light L.

### Modification Example

In the above-described embodiment, an example of the laser processing apparatus and the laser processing method according to the present disclosure is described. Accordingly, the laser processing apparatus and the laser processing method according to the present disclosure can be modified from the above description.

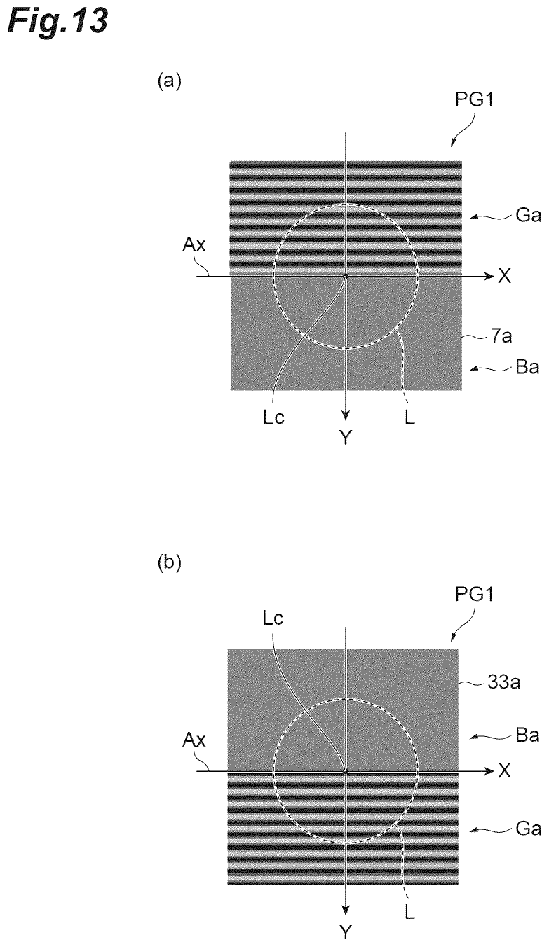

In the above-described embodiment, when setting the beam shape of the converging spot C of the laser light L to the inclined shape, offset of the spherical aberration correction pattern Ps or the coma aberration is used. However, control of the beam shape is not limited to the above-described example. Next, another example for setting the beam shape to the inclined shape will be described. As illustrated in FIG. 13(a), the laser light L may be modulated by a modulation pattern PG1 that is asymmetric with respect to an axial line Ax along the X-direction that is the processing progress direction FD to set the beam shape of the converging spot C to an inclined shape. The modulation pattern PG1 includes a grating pattern Ga on the negative side in the Y-direction in relation to the axial line Ax along the X-direction passing through the center Lc of the beam spot of the laser light L in the Y-direction, and includes a non-modulation region Ba on the positive side in the Y-direction in relation to the axial line Ax. In other words, the modulation pattern PG1 includes the grating pattern Ga only on the negative side in the Y-direction in relation to the axial line Ax. Note that FIG. 13(b) is a view obtained by inverting the modulation pattern PG1 illustrated in FIG. 13(a) so as to correspond to the entrance pupil plane 33a of the converging lens 33.

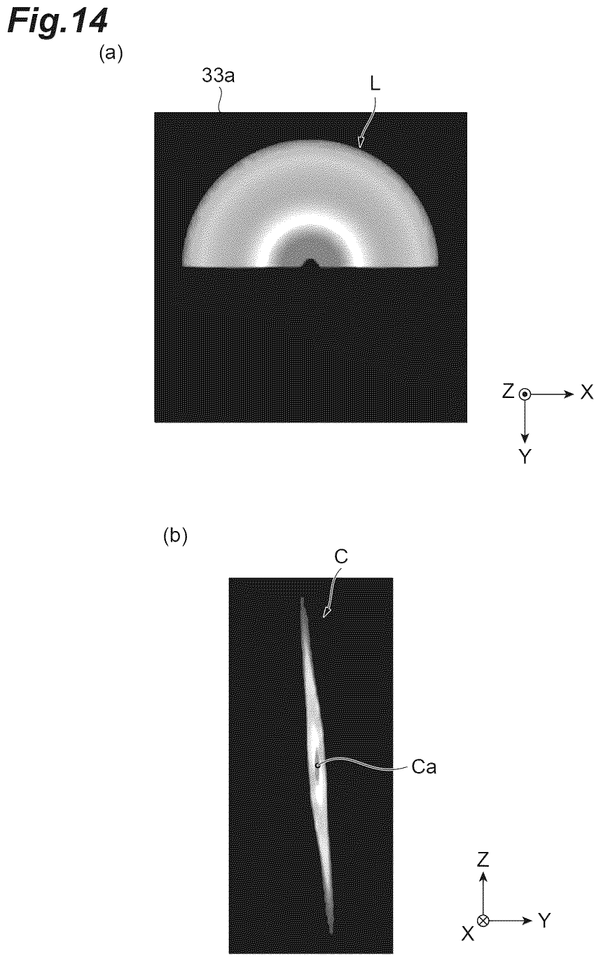

FIG. 14(a) illustrates an intensity distribution of the laser light L on the entrance pupil plane 33a of the converging lens 33. As illustrated in FIG. 14(a), a portion modulated by the grating pattern Ga in the laser light L incident to the spatial light modulator 7 is not incident to the entrance pupil plane 33a of the converging lens 33 when using the modulation pattern PG1. As a result, as illustrated in FIG. 14(b) and FIG. 15, the beam shape of the converging spot C in the YZ-plane can be set to be an inclined shape that is entirely inclined in one direction with respect to the Z-direction.

That is, in this case, the beam shape of the converging spot C is inclined to the negative side in the Y-direction with respect to the Z-direction on the first surface 11a side in relation to the center Ca of the converging spot C. That is, on the first surface 11a side in relation to the center Ca, the beam shape is inclined from the second region R2 toward the first region R1 as going from the first surface 11a toward the second surface 11b (as going toward the negative side in the Z-direction). In addition, in this case, on the second surface 11b side in relation to the center Ca of the converging spot C, the beam shape is inclined to the positive side in the Y-direction with respect to the Z-direction. That is, even on the second surface 11b side in relation to the center Ca, as going from the first surface 11a toward the second surface 11b (as going toward the negative side in the Z-direction), the beam shape is inclined from the second region R2 toward the first region R1.

Note that, in this case, the damage Dt caused by the leaked light Lt is unevenly distributed on the first region R1 side. In contrast, in a case of unevenly distributing the damage Dt caused by the leaked light Lt on the second region R2 side, in the modulation pattern PG1, positions of the grating pattern Ga and the non-modulation region Ba may be substituted with each other. In addition, respective drawings in FIG. 15(b) illustrate intensity distribution of the laser light L in the XY-plane at respective positions F1 to F7 in the Z-direction as shown in FIG. 15(a), and are actual observation results obtained by a camera.

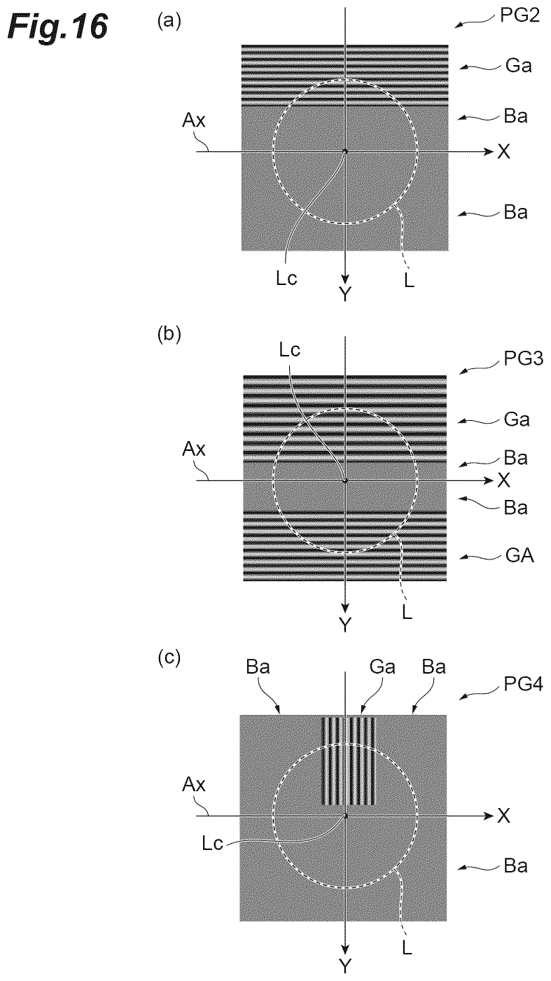

Further, modulation patterns PG2, PG3, and PG4 illustrated in FIG. 16 can also be adopted as modulation patterns asymmetric to the axial line Ax. The modulation pattern PG2 includes the non-modulation region Ba and the grating pattern Ga that are sequentially arranged in a direction away from the axial line Ax on the negative side in the Y-direction in relation to the axial line Ax, and includes the non-modulation region Ba on the positive side in the Y-direction in relation to the axial line Ax. That is, the modulation pattern PG2 includes the grating pattern Ga at a part of a region on the negative side in the Y-direction in relation to the axial line Ax.

The modulation pattern PG3 includes the non-modulation region Ba and the grating pattern Ga that are sequentially arranged in a direction away from the axial line Ax on the negative side in the Y-direction in relation to the axial line AX, and includes the non-modulation region Ba and the grating pattern Ga that are sequentially arranged in a direction away from the axial line Ax also on the positive side in the Y-direction in relation to the axial line Ax. In the modulation pattern PG3, the ratio of the non-modulation region Ba and the grating pattern Ga is made to be different between the positive side in the Y-direction and the negative side in the Y-direction in relation to the axial line Ax (the non-modulation region Ba is made to be relatively narrow on the negative side in the Y-direction), and thus the modulation pattern PG3 is asymmetric to the axial line Ax.

The modulation pattern PG4 includes the grating pattern Ga on a part of a region on the negative side in the Y-direction in relation to the axial line Ax as in the modulation pattern PG2. In the modulation pattern PG4, a region provided with the grating pattern Ga is partial also in the X-direction. That is, the modulation pattern PG4 includes the non-modulation region Ba, the grating pattern Ga, and the non-modulation region Ba that are sequentially arranged in the X-direction in a region on the negative side in the Y-direction in relation to the axial line Ax. Here, the grating pattern Ga is arranged in a region including an axial line Ay along the Y-direction passing through the center Lc of the beam spot of the laser light L in the X-direction.

With any of the modulation patterns PG2 to PG4 described above, the beam shape of the converging spot C can be set to a shape inclined from the second region R2 toward the first region R1 as going from the first surface 11a toward the second surface 11b on at least the first surface 11a side in relation to the center Ca. That is, in order to control the beam shape of the converging spot C so that the beam shape is inclined from the second region R2 toward the first region R1 as going from the first surface 11a toward the second surface 11b on at least the first surface 11a side in relation to the center Ca, an asymmetric modulation pattern including the grating pattern Ga can be used in a similar manner as in the modulation patterns PG1 to PG4 or without limitation to the modulation patterns PG1 to PG4. Furthermore, when substituting positions of the grating pattern Ga and the non-modulation region Ba with each other, an inclined shape in an opposite direction can also be formed.

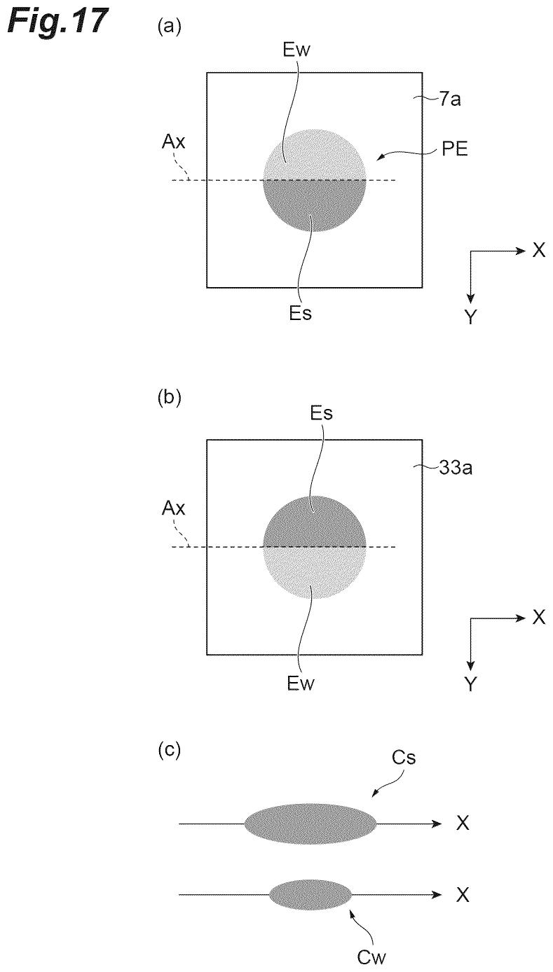

Further, the asymmetric modulation pattern for setting the beam shape of the converging spot C to an inclined shape is not limited to the pattern using the grating pattern Ga. FIG. 17 is a view illustrating another example of the asymmetric modulation pattern. As illustrated in FIG. 17(a), a modulation pattern PE includes an elliptical pattern Ew on the negative side in the Y-direction in relation to the axial line Ax and includes an elliptical pattern Es on the positive side in the Y-direction in relation to the axial line Ax. Note that, FIG. 17(b) is a view obtained by inverting the modulation pattern PE of FIG. 17(a) so as to correspond to the entrance pupil plane 33a of the converging lens 33.

As illustrated in FIG. 17(c), each of the elliptical patterns Ew and Es is a pattern for setting the beam shape of the converging spot C in the XY-plane including the X-direction and the Y-direction to an elliptical shape in which the X-direction is a longitudinal direction. However, the intensity of modulation is different between the elliptical pattern Ew and the elliptical pattern Es. More specifically, the intensity of modulation by the elliptical pattern Es is made higher than the intensity of modulation by the elliptical pattern Ew. That is, the converging spot Cs formed by the laser light L modulated by the elliptical pattern Es has an elliptical shape longer in the X-direction than the converging spot Cw formed by the laser light L modulated by the elliptical pattern Ew. Here, the elliptical pattern Es with relatively high intensity is arranged on the negative side in the Y-direction in relation to the axial line Ax.

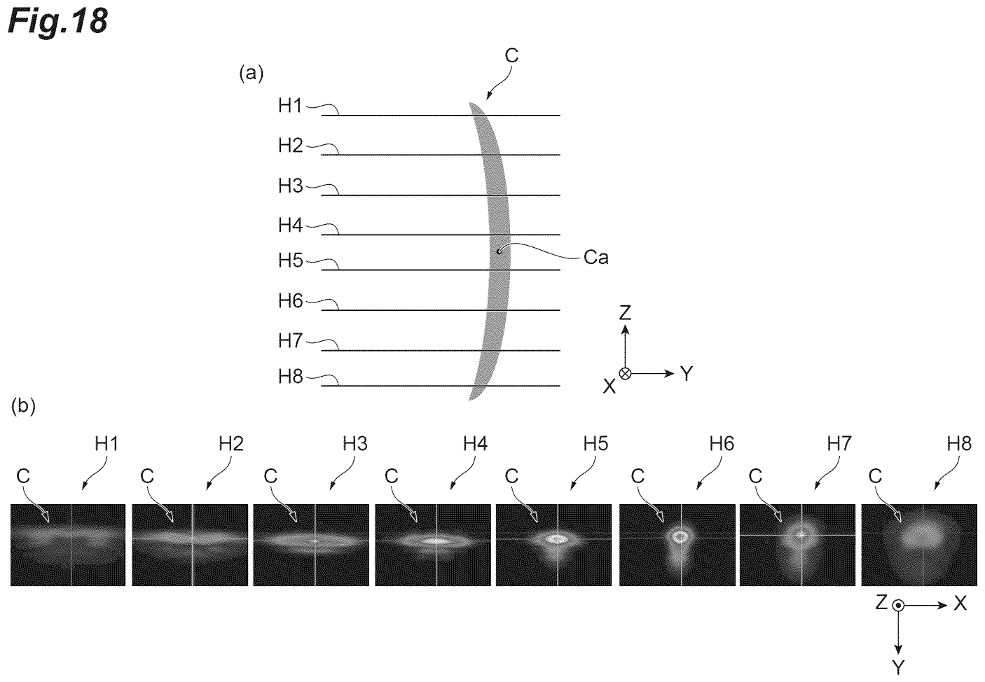

As illustrated in FIG. 18(a), when using the modulation pattern PE, the beam shape of the converging spot C in the YZ-plane is set to an inclined shape that is inclined toward the negative side in the Y-direction with respect to the Z-direction on the first surface 11a side in relation to the center Ca, that is, a shape inclined from the second region R2 toward the first region R1 as going from the first surface 11a toward the second surface 11b. Particularly, in this case, the beam shape of the converging spot C in the YZ-plane is inclined to the negative side in the Y-direction with respect to the Z-direction also on a side opposite to the first surface 11a in relation to the center Ca. That is, the beam shape becomes a shape inclined from the first region R1 toward the second region R2 as going from the first surface 11a toward the second surface 11b. As a whole, the beam shape becomes an arcuate shape.

Note that, in the modulation pattern PE, when substituting the elliptical pattern Ew and the elliptical pattern Es with each other, an inclined shape in an opposite direction can also be formed. In addition, respective drawings in FIG. 18(b) illustrate intensity distributions of the laser light L in the XY-plane in respective positions H1 to F8 in the Z-direction as illustrated in FIG. 18(a) and are actual observation results by a camera.

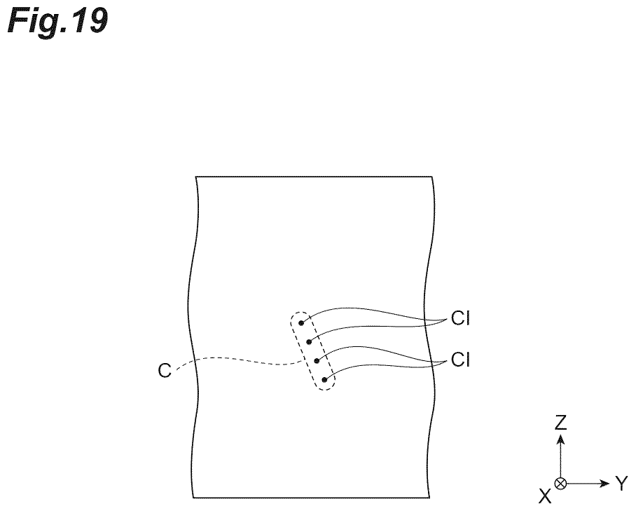

Further, the modulation pattern for setting the beam shape of the converging spot C to an inclined shape is not limited to the asymmetric pattern described above. As illustrated in FIG. 19, examples of the modulation pattern include a pattern for modulating the laser light L to form converging points CI at a plurality of positions in the YZ-plane E and to form the converging spot C having an inclined shape (including the plurality of converging points CI) over the entirety of the plurality of converging points CI. Such a modulation pattern can be formed, for example, based on an axicon lens pattern. When the modulation pattern is used, the modified region 12 itself can also be formed obliquely in the YZ-plane.

Note that, in a case of using the offset of the spherical aberration correction pattern, the coma aberration pattern, and the elliptical pattern to control the beam shape, processing with high energy can be performed as compared with the case of using the diffraction grating pattern to cut a part of the laser light. In addition, these cases are effective when emphasis is placed on the formation of a fracture. In a case of using the coma aberration pattern, the beam shape of only some of the converging spots can be inclined in a case of multifocal processing. Further, when using the axicon lens pattern, it is effective in a case where emphasis is placed on the formation of the modified region as compared with other patterns.

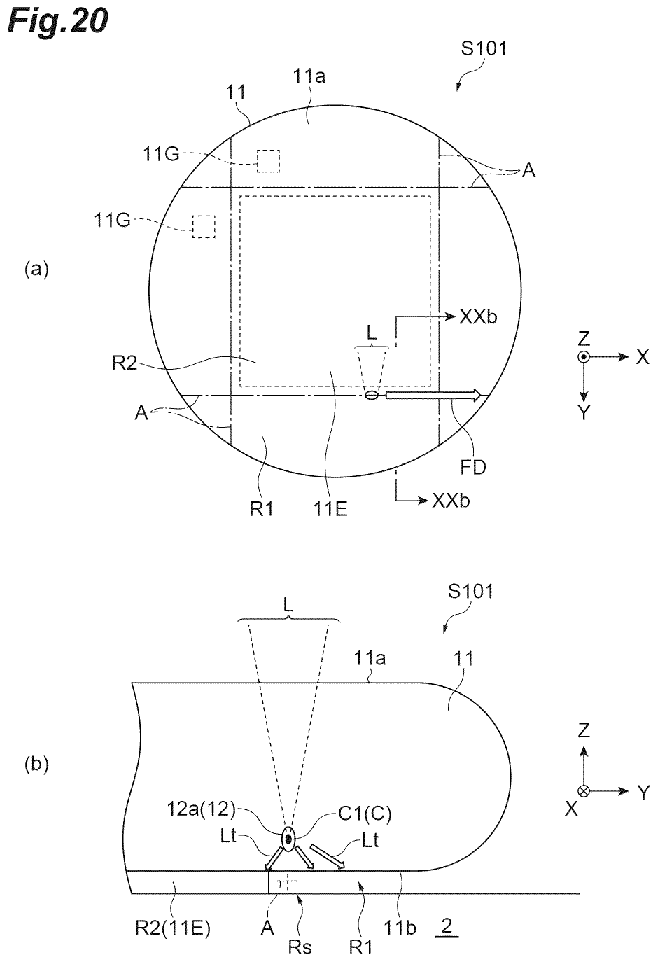

Next, a modification example of a processing object will be described. FIG. 20 is a view illustrating an object according to the modification example. FIG. 20(a) is a plan view, and FIG. 20(b) is a cross-sectional view taken along line XXb-XXb in FIG. 20(a). In this example, one large-area semiconductor device 11E (for example, Si photodiode) is formed for one object 11, and a line A is set along an outer edge of the semiconductor device 11E to surround the semiconductor device 11E. Accordingly, a second region R2 including the semiconductor device 11E and a first region R1 where the semiconductor device 11E is not formed face each other through a street region Rs where the line A is set. In this case, the second region R2 is an active region, and the first region R1 is an inactive region different from the active region. The active region is a region including a functional element such as the semiconductor device 11E. In addition, the inactive region is a region that does not include the functional element such as the semiconductor device 11E, or a region that includes an element having a certain function but the element is a test element such as TEG.

Accordingly, even in this case, partial portions of the first region R1 and the second region on the line A side have structures different from each other. Further, in this case, it is preferable to unevenly distribute the damage Dt caused by the leaked light Lt on the first region R1 side instead of the second region R2 including the semiconductor device 11E. Accordingly, even in this case, as in the above-described embodiment, at least in the process S101 and the first irradiation processing, the control unit 6 sets the beam shape of the converging spot C1 in the YZ-plane to an inclined shape that is inclined with respect to the Z-direction on at least the first surface 11a side in relation to the center Ca of the converging spot C1 by modulating the laser light L by using the spatial light modulator 7.

More specifically, also here, in the process S101 and the first irradiation processing, the control unit 6 also controls a modulation pattern to be displayed on the spatial light modulator 7 so that the beam shape of the converging spot C1 in the YZ-plane becomes a shape inclined from the second region R2 toward the first region R1 as going from the first surface 11a toward the second surface 11b on at least the first surface 11a side in relation to the center Ca of the converging spot C1. According to this, the damage Dt caused by the leaked light Lt is unevenly distributed in the first region R1 where the semiconductor device 11E is absent, and thus an influence of the damage Dt caused by the leaked light Lt is reduced. Note that, in the object 11 of this example, a TEG sensor 11G for confirming characteristics may be formed at the periphery of the semiconductor device 11E. In this case, the line A may be set to partially pass through between the semiconductor device 11E and the TEG sensor 11G. Even in this case, the beam shape of the converging spot C1 can be inclined so that the damage Dt caused by the leaked light Lt is unevenly distributed on a side opposite to the semiconductor device 11E.

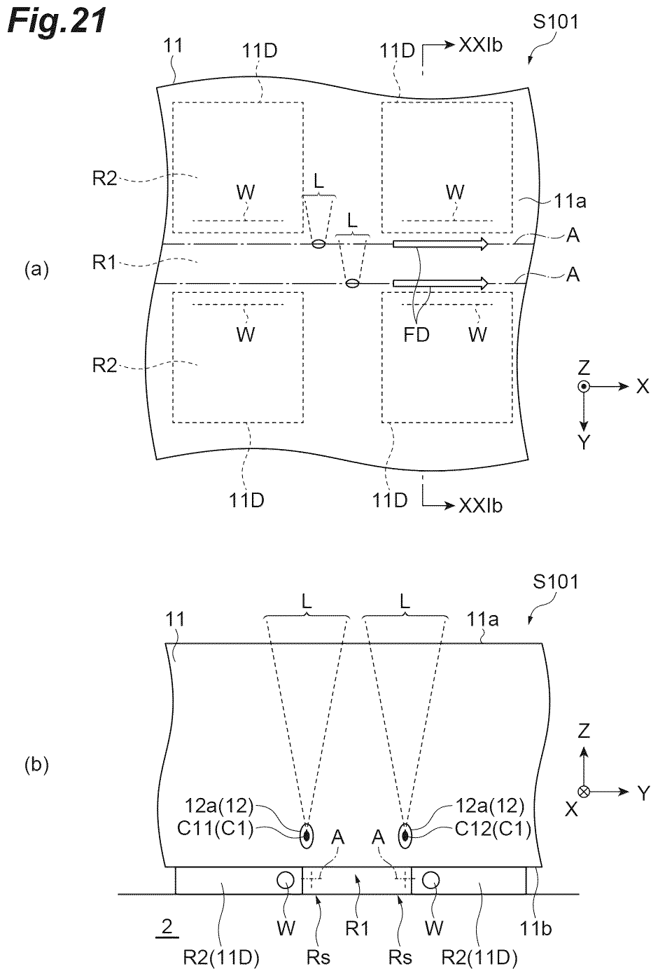

FIG. 21 is a view illustrating an object according to another modification example. FIG. 21(a) is a plan view, and FIG. 21(b) is a cross-sectional view taken along line XXIb-XXIb in FIG. 21(a). In this example, a configuration in which a plurality of semiconductor devices 11D are two-dimensionally arranged along the second surface 11b of the object 11 is similar to the above-described embodiment, but an interval between adjacent semiconductor devices 11D is set to be wider.

Therefore, in this example, two lines A are set in a region between the adjacent semiconductor devices 11D (W line processing is performed). Each of the lines A is set to be inclined to one of the semiconductor device 11D sides in relation to the center of the region between the adjacent semiconductor devices 11D.

Accordingly, in this example, a pair of street regions Rs where a pair of the lines A are set, respectively, are interposed between a pair of second regions R2 including a pair of adjacent semiconductor devices 11D, and one first region R1 (a region where the semiconductor device 11D is not formed) is provided between the pair of street regions Rs.

Accordingly, even in this case, when focusing on one line A, partial portions of the first region R1 and the second region R2 on the line A side have structures different from each other. Even in this case, the second region R2 is an active region, and the first region R1 is an inactive region different from the active region. Further, in this example, when processing any line A, it is preferable to unevenly distribute the damage Dt caused by the leaked light Lt on the first region R11 side where the semiconductor device 11D is not formed.

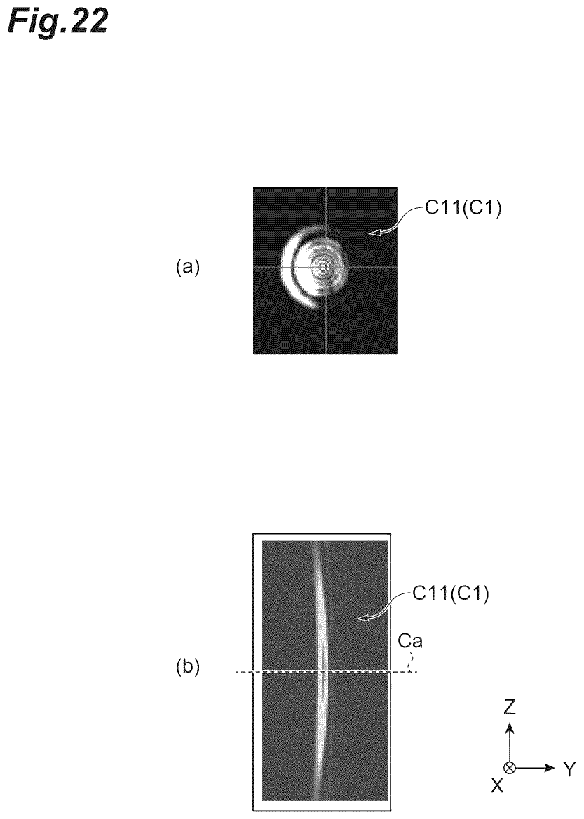

Here, in the process S101 and the first irradiation processing, in a case of processing a line A on the negative side in the Y-direction between the pair of lines A (that is, in a case where the second region R2 is positioned on the negative side in the Y-direction when viewed from the processing progress direction FD (X-direction)), as illustrated in FIG. 22, the control unit 6 forms a converging spot C11. The converging spot C11 is inclined from the second region R2 toward the first region R1 as going from the first surface 11a toward the second surface 11b (as going toward the negative side in the Z-direction) on the first surface 11a side in relation to the center Ca of the converging spot C11. Note that, the converging spot C11 is inclined from the first region R1 toward the second region R2 as going from the first surface 11a toward the second surface 11b (as going toward the negative side in the Z-direction) on the second surface 11b side in relation to the center Ca. According to this, the beam shape of the converging spot C11 in the YZ-plane is set to an arcuate shape that is convex toward the positive side in the Y-direction as a whole.

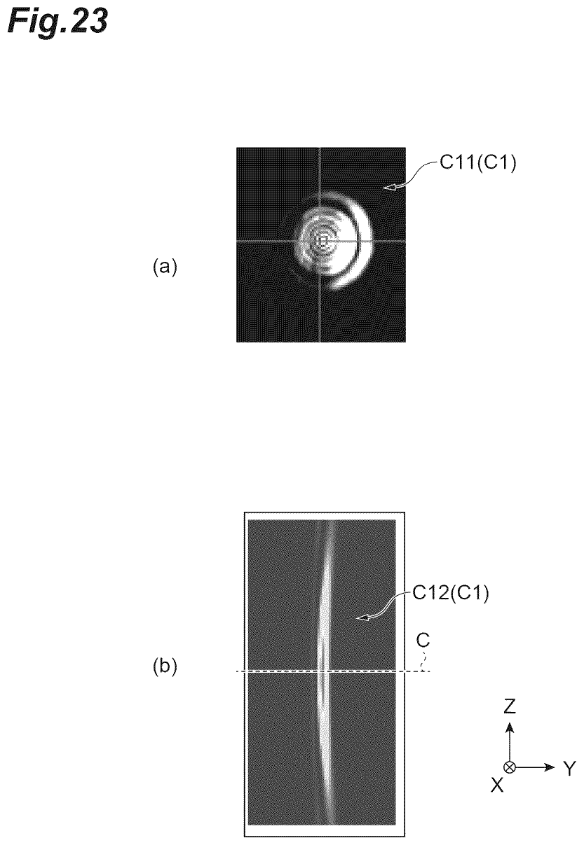

On the other hand, in the process S101 and the first irradiation processing, in a case of processing a line A on the positive side in the Y-direction between the pair of lines A (that is, in a case where the second region R2 is positioned on the positive side in the Y-direction when viewed from the processing progress direction FD (X-direction)), the control unit 6 forms a converging spot C12 as illustrated in FIG. 23. The converging spot C12 is inclined from the second region R2 toward the first region R1 as going from the first surface 11a toward the second surface 11b (as going toward the negative side in the Z-direction) on the first surface 11a side in relation to the center Ca of the converging spot C12. Note that, the converging spot C12 is inclined from the first region R1 toward the second region R2 as going from the first surface 11a toward the second surface 11b (as going toward the negative side in the Z-direction) on the second surface 11b side in relation to the center Ca. According to this, the beam shape of the converging spot C12 in the YZ-plane is set to an arcuate shape that is convex toward the negative side in the Y-direction as a whole. When forming the converging spots C11 and C12, for example, coma aberration can be used.

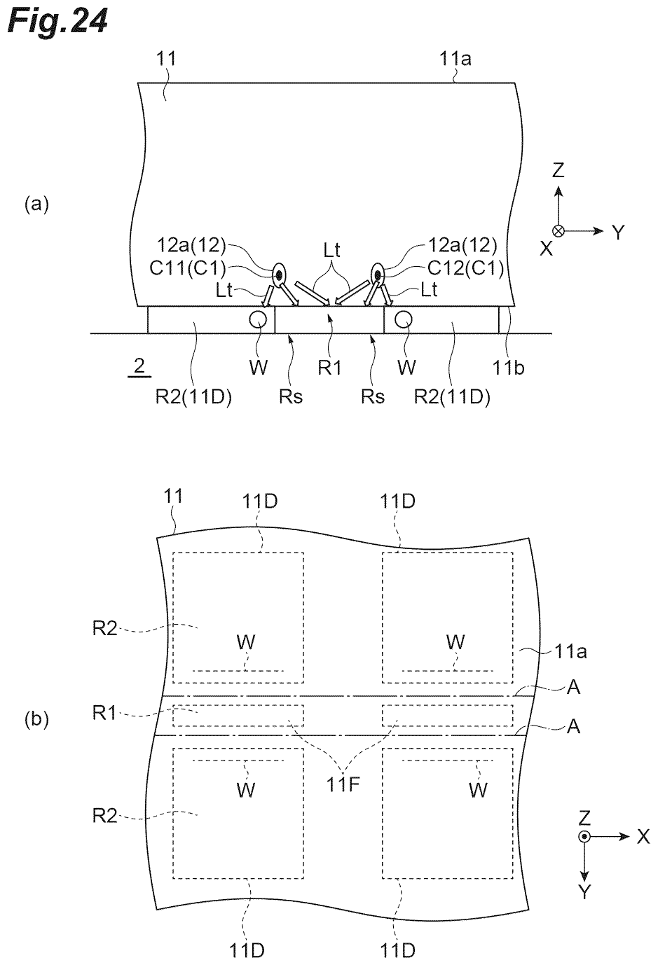

According to the above-described configurations, as illustrated in FIG. 24, even in processing of any of the pair of lines A, when unevenly distributing the damage Dt caused by the leaked light Lt on the first region R1 side where the semiconductor device 11D is not formed, it is possible to reduce an influence of the damage Dt of the leaked light Lt on the second region R2 side where the semiconductor device 11D is included. Note that, as illustrated in FIG. 24(b), in the object 11 according to this modification example, a structure 11F such as a chip for test and TEG may be formed between semiconductor devices 11D adjacent to each other. In this case, at least, in a case where a direction intersecting a direction (here, the Y-direction) in which the structure 11F is interposed between the adjacent semiconductor devices 11D is set as the processing progress direction FD, two lines A are set to straddle the structure 11F, and the W line processing is performed.

Even in this case, in a similar manner as in the above-described example, a region including the structure 11F may be set as the first region R1, and the beam shape of the converging spots C11 and C12 may be controlled so that the damage Dt of the leaked light Lt is unevenly distributed on the first region R1 side. On the other hand, in a case where a direction intersecting a direction (here, the X-direction) in which the structure 11F is not interposed between the adjacent semiconductor devices 11D is set as the processing progress direction FD, an interval between the adjacent semiconductor devices 11D may be narrower, and processing along one line A may be performed. In this case, with regard to the direction, structures of the semiconductor devices 11D adjacent to each other may be compared with each other, and the beam shape of the converging spot C1 may be controlled so that the damage Dt of the leaked light Lt is unevenly distributed on a side opposite to a side having a structure relatively vulnerable to the leaked light Lt.

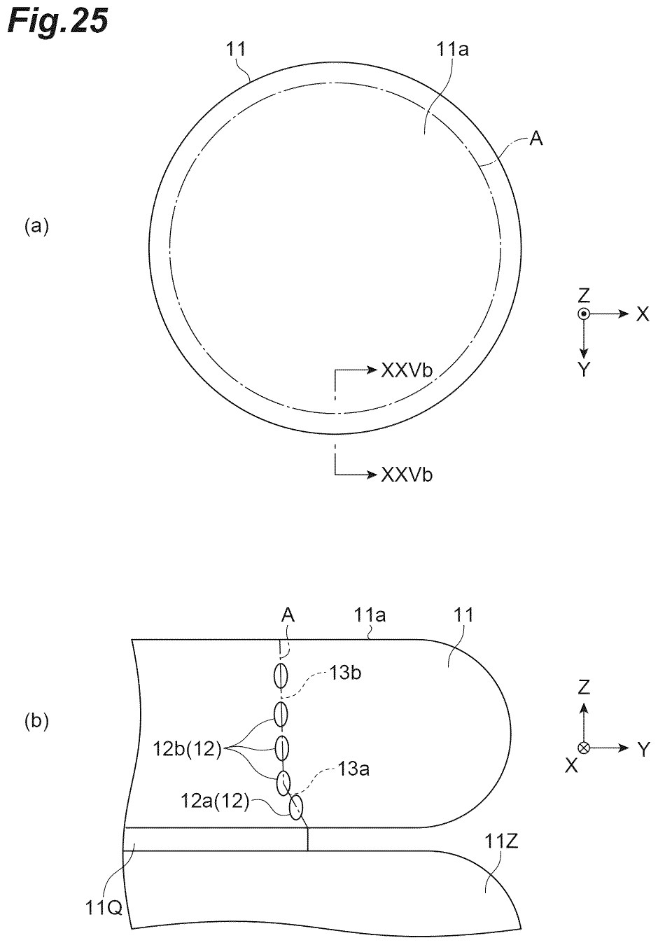

FIG. 25 is a view illustrating an object according to still another modification example. FIG. 25(a) is a plan view, and FIG. 25(b) is a cross-sectional view taken along line XXVb-XXVb in FIG. 25(a). In this example, in the object 11, a line A is set in an annular shape when viewed from the Z-direction. In addition, the object 11 is joined to an additional wafer 11Z through a device layer 11Q. Trimming is performed on the object 11. In the trimming, irradiation with the laser light L is performed along the line A to form a plurality of rows of modified regions 12a and 12b arranged in the Z-direction, a fracture (oblique fracture 13a) extending from the modified region 12a, and a fracture (vertical fracture 13b) extending from the modified region 12b. According to this, an annular region on an outer side of the line A is removed from the object 11.

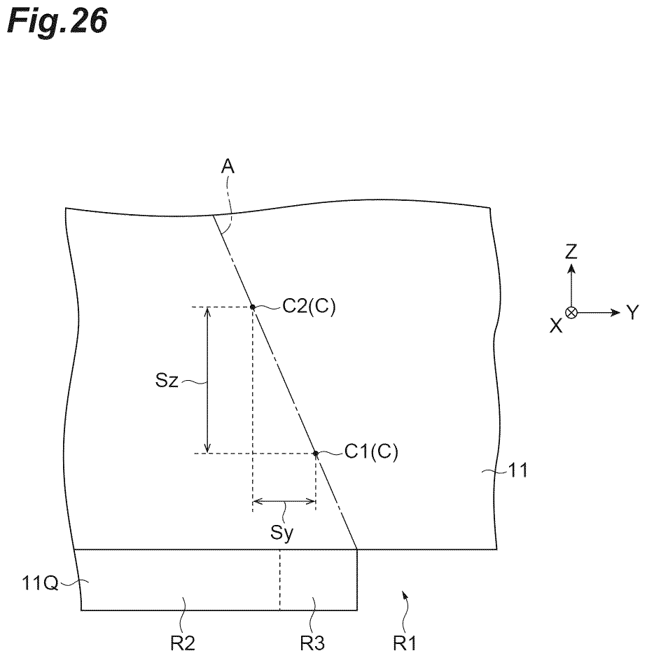

When forming the modified region 12a, the process S101 and the first irradiation processing are performed. That is, here, first, while the laser light L is incident into the object 11 from the first surface 11a side, the converging spot C1 of the laser light L is formed at a first Z-position in the Z-direction at the inside of the object 11 (refer to FIG. 26). The first Z-position is a position on the second surface 11b side in relation to the first surface 11a, and is a position where the modified region 12a on the most second surface 11b side is formed. In this state, the object 11 is irradiated with the laser light L while relatively moving the converging spot C1 of the laser light L along the line A.

At this time, the control unit 6 controls a modulation pattern to be displayed on the spatial light modulator 7 so that the beam shape of the converging spot C1 in the YZ-plane including the Y-direction intersecting the line A and the Z-direction, and the Z-direction becomes an inclined shape that is inclined with respect to the Z-direction on at least the first surface 11a side in relation to the center Ca of the converging spot CL. More specifically, in the process S101 and the first irradiation processing, the control unit 6 controls the modulation pattern to be displayed on the spatial light modulator 7 so that the beam shape of the converging spot C1 in the YZ-plane becomes a shape inclined from the second region R2 toward the first region R1 as going from the first surface 11a toward the second surface 11b on at least the first surface 11a side in relation to the center Ca of the converging spot C1.

The second region R2 stated here includes an active area inside the device layer 11Q. In addition, the first region R1 is a region (region on an outside of the device layer 11Q) where the device layer 11Q is not formed. That is, also here, the second region R2 is an active region, and the first region R1 is an inactive region different from the active region. The active region stated here is a region inside the device layer 11Q. In addition, the inactive region stated here is a region on an outside of the device layer 11Q. A third region R3 including an inactive area of an outer edge portion of the device layer 11Q is interposed between the first region R1 and the second region R2. The line A for forming at least the modified region 12a is positioned in the third region R3 when viewed from the Z-direction. Accordingly, even in this example, partial portions of the first region R1 and the second region R2 on the line A side have structures different from each other. Further, in this example, the damage Dt of the leaked light Lt is unevenly distributed on the first region R1 side opposite to the second region R2 that is an active area of the device layer 11Q.

Next, in the trimming, the process S102 and the second irradiation processing are performed. That is, as illustrated in FIG. 26, while the laser light L is incident into the object 11 from the first surface 11a side, a converging spot C2 of the laser light L is formed at a second Z-position in the Z-direction at the inside of the object 11. The second Z-position is a position on the first surface 11a side in relation to the first Z-position by a shift amount Sz, and is a position where the modified region 12b positioned on the most modified region 12a side is formed. In addition, here, the converging spot C2 is set to a second Y-position shifted by a shift amount Sy in the Y-direction from a first Y-position that is a position of the converging spot C1 in the Y-direction.

In addition, here, in the process S102 and the second irradiation processing, a laser light L2 is shaped so that the beam shape of the converging spot C2 becomes an inclined shape that is inclined in a shift direction (here, the negative side in the Y-direction) on at least the first surface 11a side in relation to the center of the converging spot C2. As an example, the beam shape of the converging spot C2 can be set to be similar to the beam shape of the converging spot C1. According to this, the oblique fracture 13a is formed to be inclined in the shift direction of the converging spot C2 in the YZ-plane. The oblique fracture 13a is formed to be inclined toward an outer side of the object 11 as going from the first surface 11a toward the second surface 11b. According to this, a fracture vertically extends from the modified region 12 to the second surface 11b side, and is suppressed from reaching the device layer 11Q and the additional wafer 11Z.

Note that, when forming a modified region other than the modified region 12b on the most modified region 12a side among a plurality of the modified regions 12b, the beam shape of the converging spot C2 can be set to a non-inclined shape along the Z-direction so that the vertical fracture 13b extending along the Z-direction is formed.

As described above, with regard to the trimming of the object 11, since the beam shape of the converging spot C1 is controlled in the process S101 and the first irradiation processing, the influence of the damage Dt of the leaked light Lt can be reduced, and since the oblique fracture 13a is formed toward the second surface 11b side, the fracture is suppressed from unintentionally progressing to the device layer 11Q and the additional wafer 11Z.

Note that, in the examples, description has been given of formation of the oblique fracture 13a during trimming, and a reduction in the influence of the damage Dt of the leaked light Lt are used in combination. However, there is a demand for forming the oblique fracture 13a even in processing other than the trimming. Therefore, in any case of forming the oblique fracture 13a, the beam shape of the converging spot C1 can be controlled to reduce the influence of the damage Dt of the leaked light Lt.

### REFERENCE SIGNS LIST

1: laser processing apparatus, 2: stage (support unit), 4, 5: drive unit (movement unit), 6: control unit, 7: spatial light modulator, 11: object, 11a: first surface, 11b: second surface, 31: light source, 33: converging lens, A: line, C, C1, C2: converging spot, R1: first region, R2: second region, W: wiring portion.

1: A laser processing apparatus, comprising:
a support unit configured to support an object;
a light source configured to output laser light;
a spatial light modulator configured to modulate the laser light output from the light source in correspondence with a modulation pattern and output the modulated laser light;
a converging lens configured to converge the laser light output from the spatial light modulator toward the object, and form a converging spot of the laser light in the object;
a movement unit configured to relatively move the converging spot with respect to the object; and
a control unit configured to control at least the light source, the spatial light modulator, and the movement unit,
wherein the object includes a first surface that becomes an incident surface of the laser light, a second surface opposite to the first surface, and first and second regions arranged on the second surface, and a line, along which the converging spot is relatively moved so as to pass between the first region and the second region, is set,
partial portions of the first region and the second region at least on the line side have structures different from each other,
the control unit executes first irradiation processing of irradiating the object with the laser light while relatively moving the converging spot along the line in a state in which the converging spot is positioned at a first Z-position on the second surface side in relation to the first surface with respect to a Z-direction intersecting the first surface and the second surface by controlling the light source, the spatial light modulator, and the movement unit, and
in the first irradiation processing, the control unit controls the modulation pattern to be displayed on the spatial light modulator so that a beam shape of the converging spot in a YZ-plane including a Y-direction intersecting the line and the Z-direction, and the Z-direction becomes an inclined shape that is inclined with respect to the Z-direction on at least the first surface side in relation to the center of the converging spot.

2: The laser processing apparatus according to claim 1,
wherein the control unit executes second irradiation processing of irradiating the object with the laser light while relatively moving the converging spot along the line in a state in which the converging spot is positioned at a second Z-position that is further spaced apart from the second surface in comparison to the first Z-position in the Z-direction by controlling the light source, the spatial light modulator, and the movement unit, and
in the second irradiation processing, the control unit sets the beam shape of the converging spot in the YZ-plane to a non-inclined shape along the Z-direction through control of the spatial light modulator.

3: The laser processing apparatus according to claim 1,
wherein the first region and the second region are semiconductor devices, respectively,
the second region is provided with a wiring portion at the partial portion, and
in the first irradiation processing, the control unit controls the modulation pattern to be displayed on the spatial light modulator so that the beam shape of the converging spot in the YZ-plane becomes a shape that is inclined from the second region toward the first region as going from the first surface to the second surface on at least the first surface side in relation to the center of the converging spot.

4: The laser processing apparatus according to claim 1,
wherein the second region is an active region,
the first region is a region different from the active region, and
in the first irradiation processing, the control unit controls the modulation pattern to be displayed on the spatial light modulator so that the beam shape of the converging spot in the YZ-plane becomes a shape that is inclined from the second region toward the first region as going from the first surface to the second surface on at least the first surface side in relation to the center of the converging spot.

5: The laser processing apparatus according to claim 1,
wherein the modulation pattern includes a coma aberration pattern configured to apply coma aberration to the laser light, and
in the first irradiation processing, the control unit sets the beam shape to the inclined shape by controlling the coma aberration with the coma aberration pattern.

6: A laser processing method of irradiating an object, which includes a first surface, a second surface opposite to the first surface, and first and second regions arranged along the second surface and in which a line is set to pass between the first region and the second region, with laser light, the method comprising:
a first irradiation process of irradiating the object with the laser light while relatively moving a converging spot along the line in a state in which the converging spot of the laser light is positioned at a first Z-position on the second surface side in relation to the first surface with respect to a Z-direction intersecting the first surface and the second surface,
wherein partial portions of the first region and the second region at least on the line side have structures different from each other, and
in the first irradiation process, the laser light is modulated so that a beam shape of the converging spot in a YZ-plane including a Y-direction intersecting the line and the Z-direction, and the Z-direction becomes an inclined shape that is inclined with respect to the Z-direction on at least the first surface side in relation to the center of the converging spot.
